(19) United States
(12) Patent Application Publication
(10) Pub. No.: US 2026/0045280 A1
(43) Pub. Date: Feb. 12, 2026

(54) SEMICONDUCTOR DEVICE AND METHOD FOR MANUFACTURING SEMICONDUCTOR DEVICE

(71) Applicant: Kioxia Corporation, Tokyo (JP)

(72) Inventors: Masayoshi TAGAMI, Kuwana Mie (JP); Tsuyoshi HIRAYU, Yokkaichi Mie (JP); Hiroyuki KUTSUKAKE, Kuwana Mie (JP)

(21) Appl. No.: 19/070,210

(22) Filed: Mar. 4, 2025

(30) Foreign Application Priority Data
Aug. 9, 2024 (JP) 2024-134262

(51) Int. Cl. G11C 5/06; G11C 16/04; G11C 16/08; H01L 23/00; H01L 25/065; H10B 43/10; H10B 43/35; H10B 80/00

(52) U.S. Cl. CPC G11C 5/063; G11C 16/0483; G11C 16/08; H01L 24/08; H01L 25/0657; H10B 43/10; H10B 43/35; H10B 80/00; H01L 2224/08235; H01L 2225/06541

(57) ABSTRACT

A semiconductor device includes a first chip and a second chip. The first chip includes a first substrate on which a first transistor is formed. The second chip is provided above the first chip and includes a second substrate on which a second transistor is formed. The second substrate includes a first insulating region and a second insulating region each penetrating the second substrate. The first chip and the second chip are electrically connected to each other via a first group of through vias penetrating the first insulating region and a second group of through vias penetrating the second insulating region. The first group of through vias is arranged at a first pitch, and the second group of through vias is arranged at a second pitch different from the first pitch.

### CROSS-REFERENCE TO RELATED APPLICATION

This application is based upon and claims the benefit of priority from Japanese Patent Application No. 2024-134262, filed Aug. 9, 2024, the entire contents of which are incorporated herein by reference.

### FIELD

Embodiments described herein relate generally to a semiconductor device and a method for manufacturing the semiconductor device.

### BACKGROUND

A NAND flash memory is known as a semiconductor device.

Examples of related art include US-A-2023/0420007, JP-A-2012-39005, and “3D Sequential Process Integration for CMOS Image Sensor”, 2021 IEEE International Electron Devices Meeting (IEDM), 2021, by K. Nakazawa, J. Yamamoto, S. Mori, S. Okamoto, A. Shimizu, K Baba, N. Fujii, M. Uehara, K. Hiramatsu, H. Kumano, A. Matsumoto, K. Zaitsu, H. Ohnuma, K. Tatani, T. Hirano, and H. Iwamoto.

### DESCRIPTION OF THE DRAWINGS

FIG. 1 is a block diagram showing an example of the overall configuration of a memory system including a semiconductor device according to an embodiment.

FIG. 2 is a circuit diagram showing an example of a circuit configuration of a memory cell array in the semiconductor device according to the embodiment.

FIG. 3 is a circuit diagram showing an example of a circuit configuration of a row decoder module in the semiconductor device according to the embodiment.

FIG. 4 is a circuit diagram showing an example of a circuit configuration of a sense amplifier module in the semiconductor device according to the embodiment.

FIG. 5 is a perspective view diagram showing an example of an appearance of the semiconductor device according to the embodiment.

FIG. 6 is a plan view diagram showing an example of a planar layout of the semiconductor device according to the embodiment.

FIG. 7 is a plan view diagram showing an example of a planar layout of a memory cell array in a core region of the semiconductor device according to the embodiment.

FIG. 8 is a plan view diagram showing an example of a planar layout in a memory region of the memory cell array in the semiconductor device according to the embodiment.

FIG. 9 is a cross-sectional view diagram showing an example of a cross-sectional structure of the memory region of the memory cell array in the semiconductor device according to the embodiment.

FIG. 10 is a cross-sectional view diagram showing an example of a cross-sectional structure of a memory pillar in the semiconductor device according to the embodiment.

FIG. 11 is a plan view diagram showing an example of a planar layout in a contact region of the memory cell array in the semiconductor device according to the embodiment.

FIG. 12 is a cross-sectional view diagram showing an example of a cross-sectional structure of the contact region of the memory cell array in the semiconductor device according to the embodiment.

FIG. 13 is a cross-sectional view diagram showing an example of a cross-sectional structure of a core region of the semiconductor device according to the embodiment.

FIG. 14 is a plan view diagram showing an example of a planar layout of through vias in the memory region of the semiconductor device according to the embodiment.

FIG. 15 is a plan view diagram showing another example of the planar layout of the through vias in the memory region of the semiconductor device according to the embodiment.

FIG. 16 is a plan view diagram showing an example of a planar layout of through vias in the contact region of the semiconductor device according to the embodiment.

FIG. 17 is a cross-sectional view diagram showing an example of a cross-sectional structure of a peripheral region of the semiconductor device according to the embodiment.

FIG. 18 is a plan view diagram showing an example of a planar layout of through vias in the peripheral region of the semiconductor device according to the embodiment.

FIG. 19 is a plan view diagram showing an example of a planar layout of bonding pads in the peripheral region of the semiconductor device according to the embodiment.

FIG. 20 is a plan view diagram showing another example of a planar layout of the through vias in the peripheral region of the semiconductor device according to the embodiment.

FIG. 21 is a plan view diagram showing another example of a planar layout of the bonding pads in the peripheral region of the semiconductor device according to the embodiment.

FIG. 22 is a cross-sectional view diagram showing an example of a cross-sectional structure of a wall region of the semiconductor device according to the embodiment.

FIG. 23 is a plan view diagram showing an example of a planar layout of through vias in the wall region of the semiconductor device according to the embodiment.

FIG. 24 is a flowchart showing an example of a method for manufacturing the semiconductor device according to the embodiment.

FIG. 25 is a cross-sectional view diagram showing an example of a cross-sectional structure of the semiconductor device according to the embodiment during the manufacture thereof.

FIG. 26 is a cross-sectional view diagram showing an example of a cross-sectional structure of the semiconductor device according to the embodiment during the manufacture thereof.

FIG. 27 is a cross-sectional view diagram showing an example of a cross-sectional structure of the semiconductor device according to the embodiment during the manufacture thereof.

FIG. 28 is a cross-sectional view diagram showing an example of a cross-sectional structure of the semiconductor device according to the embodiment during the manufacture thereof.

FIG. 29 is a cross-sectional view diagram showing an example of a cross-sectional structure of the semiconductor device according to the embodiment during the manufacture thereof.

FIG. 30 is a cross-sectional view diagram showing an example of a cross-sectional structure of the semiconductor device according to the embodiment during the manufacture thereof.

FIG. 31 is a cross-sectional view diagram showing an example of a cross-sectional structure of the semiconductor device according to the embodiment during the manufacture thereof.

FIG. 32 is a cross-sectional view diagram showing an example of a cross-sectional structure of the semiconductor device according to the embodiment during the manufacture thereof.

FIG. 33 is a cross-sectional view diagram showing an example of a cross-sectional structure of the semiconductor device according to the embodiment during the manufacture thereof.

FIG. 34 is a cross-sectional view diagram showing an example of a cross-sectional structure of the semiconductor device according to the embodiment during the manufacture thereof.

FIG. 35 is a cross-sectional view diagram showing an example of a cross-sectional structure of the semiconductor device according to the embodiment during the manufacture thereof.

FIG. 36 is a cross-sectional view diagram showing an example of a cross-sectional structure of the semiconductor device according to the embodiment during the manufacture thereof.

FIG. 37 is a cross-sectional view diagram showing an example of a cross-sectional structure of the semiconductor device according to the embodiment during the manufacture thereof.

FIG. 38 is a cross-sectional view diagram showing an example of a cross-sectional structure of the semiconductor device according to the embodiment during the manufacture thereof.

FIG. 39 is a cross-sectional view diagram showing an example of a cross-sectional structure of the semiconductor device according to the embodiment during the manufacture thereof.

FIG. 40 is a cross-sectional view diagram showing an example of a cross-sectional structure of the semiconductor device according to the embodiment during the manufacture thereof.

FIG. 41 is a cross-sectional view diagram showing an example of a cross-sectional structure of the semiconductor device according to the embodiment during the manufacture thereof.

FIG. 42 is a cross-sectional view diagram showing an example of a cross-sectional structure of the semiconductor device according to the embodiment during the manufacture thereof.

FIG. 43 is a cross-sectional view diagram showing an example of a cross-sectional structure of the semiconductor device according to the embodiment during the manufacture thereof.

FIG. 44 is a cross-sectional view diagram showing an example of a cross-sectional structure of a core region of a semiconductor device according to a first modification.

FIG. 45 is a cross-sectional view diagram showing an example of a cross-sectional structure of a peripheral region of the semiconductor device according to the first modification.

FIG. 46 is a cross-sectional view diagram showing an example of a cross-sectional structure of a wall region of the semiconductor device according to the first modification.

FIG. 47 is a flowchart showing an example of a method for manufacturing the semiconductor device according to the first modification.

FIG. 48 is a cross-sectional view diagram showing an example of a cross-sectional structure of the semiconductor device according to the first modification during the manufacture thereof.

FIG. 49 is a cross-sectional view diagram showing an example of a cross-sectional structure of the semiconductor device according to the first modification during the manufacture thereof.

FIG. 50 is a cross-sectional view diagram showing an example of a cross-sectional structure of a peripheral region of a semiconductor device according to a second modification.

FIG. 51 is a cross-sectional view diagram showing an example of a cross-sectional structure when a plurality of semiconductor devices according to the second modification are stacked.

FIG. 52 is a cross-sectional view diagram showing in an XZ plane an example of a structure of another transistor applicable to the semiconductor devices according to the embodiment, the first modification, and the second modification.

FIG. 53 is a cross-sectional view diagram showing the transistor in FIG. 52 in a YZ plane.

FIG. 54 is a cross-sectional view diagram showing in the XZ plane an example of a structure of another transistor applicable to the semiconductor devices according to the embodiment, the first modification, and the second modification.

FIG. 55 is a cross-sectional view diagram showing the transistor in FIG. 54 in a YZ plane.

### DETAILED DESCRIPTION

Embodiments provide a semiconductor device of which chip area can be reduced and a method for manufacturing the semiconductor device.

In general, according to an embodiment, a semiconductor device includes a first chip and a second chip. The first chip includes a first substrate on which a first transistor is formed. The second chip is provided above the first chip and includes a second substrate on which a second transistor is formed. The second substrate includes a first insulating region and a second insulating region each penetrating the second substrate. The first chip and the second chip are electrically connected to each other via a first group of through vias penetrating the first insulating region and a second group of through vias penetrating the second insulating region. The first group of through vias is arranged at a first pitch, and the second group of through vias is arranged at a second pitch different from the first pitch.

Hereinafter, an embodiment will be described with reference to the drawings. The embodiment describes a device and method for embodying the technical ideas of the present disclosure. The drawings are schematic or conceptual. The dimensions and ratios in each drawing are not necessarily the same as those in reality. The illustration of the configuration is omitted as appropriate. Hatching added to the plan view does not necessarily relate to the material or properties of the elements. In this specification, elements having substantially the same functions and configurations are given the same reference numerals. Numbers, letters, or the like appended to a reference number are used to distinguish between similar elements that are referred to by the same reference number.

### <1> Embodiment

The configuration of a semiconductor device according to an embodiment t will be described. The semiconductor device according to the embodiment includes a memory cell and a CMOS circuit for accessing the memory cell, and has a structure in which the CMOS circuit is disposed on a plurality of stacked substrates.

### <1-1> Overall Configuration of Semiconductor Device

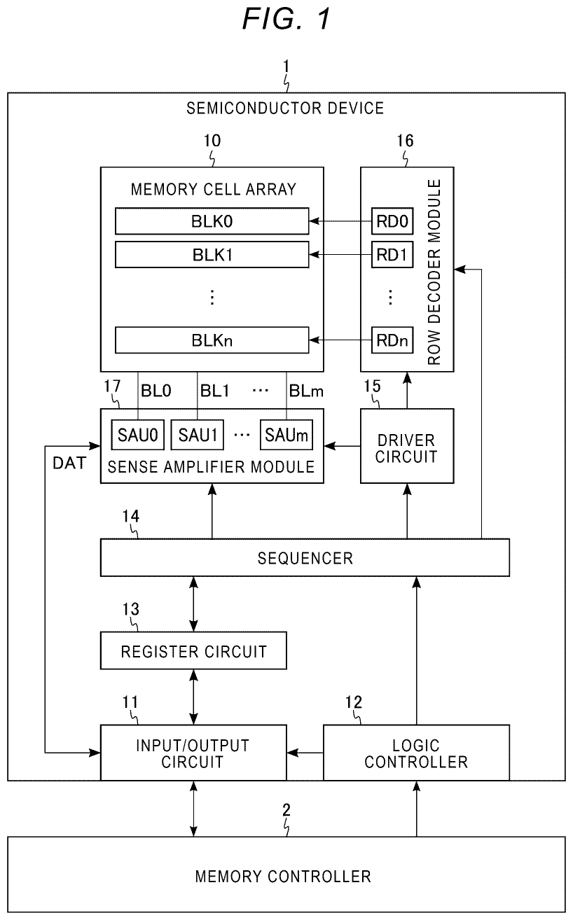

FIG. 1 is a block diagram showing an example of the overall configuration of a memory system including a semiconductor device according to an embodiment. As shown in FIG. 1, a semiconductor device 1 is controlled by an external memory controller 2. The semiconductor device 1 is, for example, a NAND flash memory capable of storing data in a non-volatile manner. The semiconductor device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer equal to or greater than 1). A block BLK is a set of a plurality of memory cells. The block BLK corresponds to, for example, a unit of data erase. The block BLK includes a plurality of pages. The page corresponds to a unit in which data is read and written. Although not shown, the memory cell array 10 is provided with a plurality of bit lines BL0 to BLm (where “m” is an integer equal to or greater than 1) and a plurality of word lines WL. Each memory cell is, for example, associated with one bit line BL and one word line WL.

The input/output circuit 11 is an interface circuit that controls transmission and reception of input/output signals to and from the memory controller 2. Examples of the input/output signals include data DAT, status information, address information, commands, and the like. The input/output circuit 11 can input and output the data DAT to and from the sense amplifier module 17 and the memory controller 2, respectively. The input/output circuit 11 can output the status information transferred from the register circuit 13 to the memory controller 2. The input/output circuit 11 can output each of the address information and the command transferred from the memory controller 2, to the register circuit 13.

The logic controller 12 controls each of the input/output circuit 11 and the sequencer 14, based on the control signal input from the memory controller 2. For example, the logic controller 12 controls the sequencer 14 to enable the semiconductor device 1. The logic controller 12 notifies the input/output circuit 11 that the input/output signal received by the input/output circuit 11 is a command, address information, or the like. The logic controller 12 instructs the input/output circuit 11 to input or output an input/output signal.

The register circuit 13 temporarily stores status information, address information, and commands. The status information is updated under the control of the sequencer 14 and transferred to the input/output circuit 11. The address information includes a block address, a page address, a column address, and the like. The commands include instructions regarding various operations of the semiconductor device 1.

The sequencer 14 controls the overall operation of the semiconductor device 1. The sequencer 14 executes a read operation, a write operation, an erase operation, or the like, based on the command and address information stored in the register circuit 13.

The driver circuit 15 generates voltages used in a read operation, a write operation, an erase operation, or the like. The driver circuit 15 then supplies the generated voltages to the row decoder module 16, the sense amplifier module 17, or the like.

The row decoder module 16 is a circuit used to select a block BLK to be operated and to transfer a voltage to wiring such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers the voltage generated by the driver circuit 15 to various wirings provided in the memory cell array 10. The sense amplifier module 17 is a circuit used for transferring a voltage to each bit line BL and for reading data. The sense amplifier module 17 includes a plurality of sense amplifier units SAU0 to SAUm. The sense amplifier units SAU0 to SAUm are associated with a plurality of bit lines BL0 to BLm, respectively. Each sense amplifier unit SAU includes a sense amplifier capable of determining data based on the voltage of an associated bit line BL, a latch circuit for temporarily storing data, and the like.

Furthermore, a set including the semiconductor device 1 and the memory controller 2 may form one semiconductor device. Examples of such semiconductor devices include memory cards such as SD™ cards and solid state drives (SSDs).

### <1-2> Circuit Configuration of Semiconductor Device

The circuit configuration of the semiconductor device 1 will be described.

### <1-2-1> Circuit Configuration of Memory Cell Array

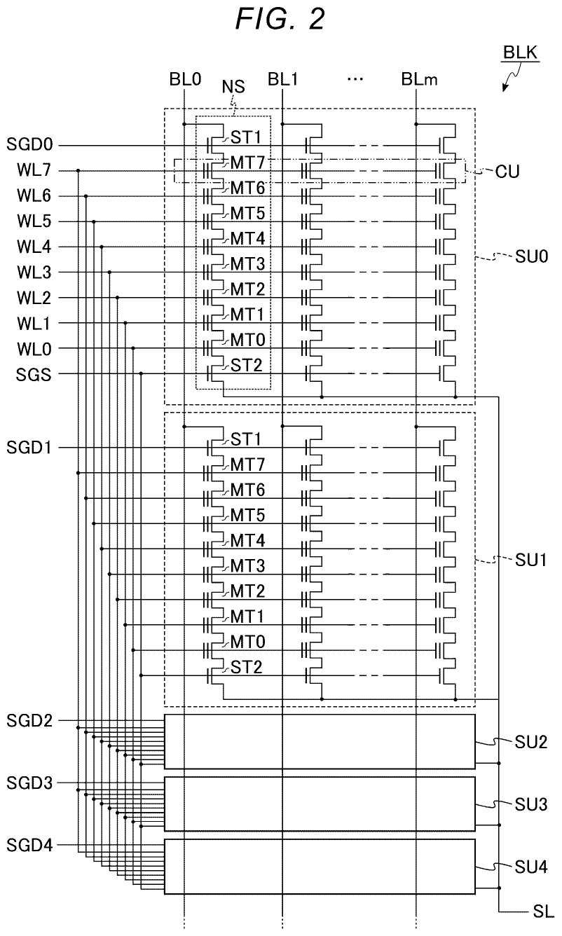

FIG. 2 is a circuit diagram showing an example of a circuit configuration of the memory cell array 10 in the semiconductor device 1 according to the embodiment. FIG. 2 shows one block BLK among the plurality of blocks BLK in the memory cell array 10. As shown in FIG. 2, the block BLK includes, for example, five string units SU0 to SU4. Select gate lines SGD0 to SGD4 and SGS and word lines WL0 to WL7 are provided for each block BLK. The bit lines BL0 to BLm and a source line SL are shared by the plurality of blocks BLK.

Each string unit SU includes a plurality of NAND strings NS. The plurality of NAND strings NS are associated with the bit lines BL0 to BLm, respectively. That is, each bit line BL is shared by NAND strings NS to which the same column address is assigned among the plurality of blocks BLK. Each NAND string NS is connected between the associated bit line BL and the source line SL. Each NAND string NS includes, for example, memory cell transistors MT0 to MT7 and select transistors ST1 and ST2. Each memory cell transistor MT is a memory cell having a control gate and a charge storage layer, and stores (stores) data in a non-volatile manner. Each of the select transistors ST1 and ST2 is used to select a string unit SU.

In each NAND string NS, the select transistor ST1, the memory cell transistors MT7 to MT0, and the select transistor ST2 are connected in series in this order. Specifically, the drain and the source of the select transistor ST1 are connected to the associated bit line BL and the drain of the memory cell transistor MT7, respectively. The drain and the source of the select transistor ST2 are connected to the source of the memory cell transistor MT0 and the source line SL, respectively. The memory cell transistors MT0 to MT7 are connected in series between the select transistors ST1 and ST2.

The select gate lines SGD0 to SGD4 are associated with the string units SU0 to SU4, respectively. Each select gate line SGD is connected to the gate of each of the plurality of select transistors ST1 in the associated string unit SU. The select gate line SGS is connected to the gate of each of the plurality of select transistors ST2 in the associated block BLK. The word lines WL0 to WL7 are connected to the control gates of the memory cell transistors MT0 to MT7, respectively.

A set of a plurality of memory cell transistors MT connected to a common word line WL in the same string unit SU is called, for example, a “cell unit CU”. For example, the storage capacity of a cell unit CU in which each memory cell transistor MT stores one bit of data is defined as “one page of data”. The cell unit CU can have a storage capacity of two or more pages of data depending on the number of bits of data stored in each memory cell transistor MT.

Furthermore, the circuit configuration of the memory cell array 10 in the semiconductor device 1 according to the embodiment may be other configurations. For example, the number of string units SU in each block BLK, and the number of memory cell transistors MT and select transistors ST1 and ST2 in each NAND string NS can be designed to be any suitable number.

### <1-2-2> Circuit Configuration of Row Decoder Module

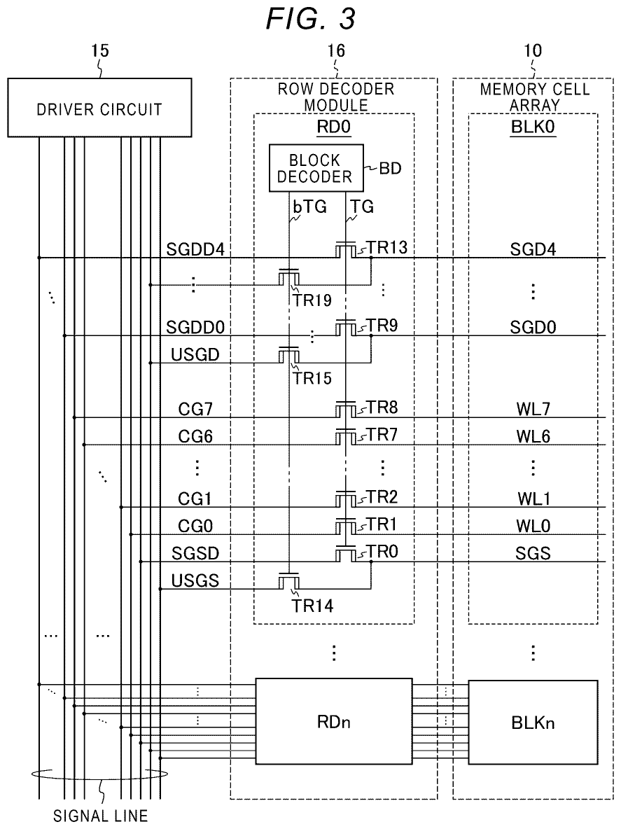

FIG. 3 is a circuit diagram showing an example of a circuit configuration of the row decoder module 16 in the semiconductor device 1 according to the embodiment. FIG. 3 shows the connection relationship between the row decoder module 16 and the driver circuit 15 and the memory cell array 10, and also shows a detailed circuit configuration of the row decoder RD0. As shown in FIG. 3, each row decoder RD is connected to the driver circuit 15 via signal lines CGO to CG7, SGDD0 to SGDD4, SGSD, USGD, and USGS. Each row decoder RD is connected to an associated block BLK via word lines WL0 to WL7 and select gate lines SGS and SGD0 to SGD4.

Focusing on the row decoder RD0, the connection relationship between each element of the row decoder RD and the driver circuit 15 and the block BLK0 will be described below. Furthermore, the configurations of the other row decoders RD are similar to the configuration of the row decoder RD0, except that the associated blocks BLK are different. The row decoder RD0 includes, for example, transistors TR0 to TR19, transfer gate lines TG and bTG, and a block decoder BD.

Each of the transistors TR0 to TR19 is a N-type high-breakdown voltage MOS transistor (hereinafter also referred to as a “High-Voltage (HV) transistor”). The drain and the source of the transistor TR0 are connected to the signal line SGSD and the select gate line SGS, respectively. The drains of the transistors TRI to TR8 are connected to the signal lines CGO to CG7, respectively. The sources of the transistors TRI to TR8 are connected to the word lines WL0 to WL7, respectively. The drains of the transistors TR9 to TR13 are connected to the signal lines SGDD0 to SGDD4, respectively. The sources of the transistors TR9 to TR13 are connected to the select gate lines SGD0 to SGD4, respectively. The drain and the source of the transistor TR14 are connected to the signal line USGS and the select gate line SGS, respectively. The drains of the transistors TR15 to TR19 are connected to the signal line USGD. The sources of the transistors TR15 to TR19 are connected to the select gate lines SGD0 to SGD4, respectively. The gates of the transistors TR0 to TR13 are connected to the transfer gate line TG. The gates of the transistors TR14 to TR19 are connected to the transfer gate line bTG.

The block decoder BD is a circuit having a function of decoding a block address. The block decoder BD applies a predetermined voltage to each of the transfer gate lines TG and bTG based on the result of decoding the block address. Specifically, the block decoder BD corresponding to the selected block BLK applies “H” level and “L” level voltages to the transfer gate lines TG and bTG, respectively. The block decoder BD corresponding to the unselected block BLK applies “L” level and “H” level voltages to the transfer gate lines TG and bTG, respectively. Thus, the voltages of the signal lines CGO to CG7 are transferred to the word lines WL0 to WL7 of the selected block BLK, respectively, the voltages of the signal lines SGDD0 to SGDD4 and SGSD are transferred to the select gate lines SGD0 to SGD4 and SGS of the selected block BLK, respectively, and the voltages of the signal lines USGD and USGS are transferred to the select gate lines SGD and SGS of the unselected blocks BLK, respectively.

Furthermore, the row decoder module 16 may have other circuit configurations. For example, the number of transistors TR in the row decoder module 16 can be changed according to the number of wirings provided in each block BLK. The signal line CG may be called a “global word line” because the signal line CG is shared among a plurality of blocks BLK. The word lines WL may be called “local word lines” because the word line WL is provided for each block BLK. Each of the signal lines SGDD and SGSD may be called a “global transfer gate line” because each line is shared among the plurality of blocks BLK. Each of the select gate lines SGD and SGS may be called a “local transfer gate line” because each line is provided for each block BLK.

### <1-2-3> Circuit Configuration of Sense Amplifier Module

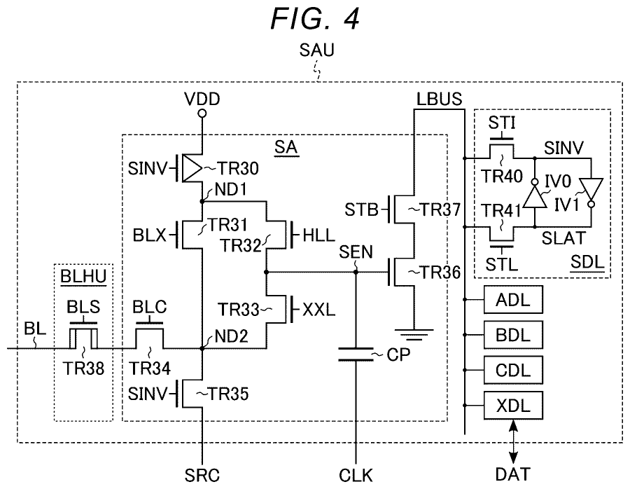

FIG. 4 is a circuit diagram showing an example of a circuit configuration of the sense amplifier module 17 in the semiconductor device 1 according to the embodiment. FIG. 4 shows the circuit configuration of one sense amplifier unit SAU. As shown in FIG. 4, the sense amplifier unit SAU includes, for example, a sense amplifier section SA, a bit line connection section BLHU, latch circuits SDL, ADL, BDL, CDL, and XDL, and a bus LBUS. The sense amplifier section SA and the latch circuits SDL, ADL, BDL, CDL, and XDL are configured to be able to transmit and receive data via the bus LBUS, for example.

The sense amplifier section SA is a circuit used for determining a value of data based on the voltage of the bit line BL and for applying a voltage to the bit line BL. When a control signal STB is asserted during a read operation, the sense amplifier section SA determines whether the data read from the selected memory cell transistor MT is “0” or “1” based on the voltage of the associated bit line BL. Each of the latch circuits SDL, ADL, BDL, CDL, and XDL is a circuit capable of temporarily storing data. The latch circuit XDL is used for inputting and outputting data DAT between the sense amplifier unit SAU and the input/output circuit 11. The latch circuit XDL can also be used as a cache memory.

The sense amplifier section SA includes transistors TR30 to TR37, a capacitor CP, and nodes ND1, ND2, SEN, and SRC. The bit line connection section BLHU is a switch circuit for preventing a high voltage applied to the channel of the NAND string NS in an erase operation from being applied to the circuit in the sense amplifier section SA. The bit line connection section BLHU includes a transistor TR38. The latch circuit SDL includes inverters IV0 and IV1, transistors TR40 and TR41, and nodes SINV and SLAT. The transistor TR30 is a P-type MOS transistor. Each of the transistors TR31 to TR38, TR40, and TR41 is an N-type MOS transistor. The transistor TR38 is an N-type MOS transistor (HV transistor) having a higher breakdown voltage than the N-type transistors in the sense amplifier section SA. In the following, a transistor with a lower breakdown voltage than an HV transistor is also referred to as a “Low-Voltage (LV) transistor”.

The gate of the transistor TR30 is connected to the node SINV. The source of the transistor TR30 is connected to a power supply line. The drain of the transistor TR30 is connected to the node ND1. The node ND1 is connected to the drains of the transistors TR31 and TR32. The sources of the transistors TR31 and TR32 are connected to the nodes ND2 and SEN, respectively. The nodes ND2 and SEN are connected to the source and drain of the transistor TR33, respectively. The node ND2 is connected to the drains of the transistors TR34 and TR35. The source of the transistor TR35 is connected to the node SRC. The gate of the transistor TR35 is connected to the node SINV. The node SEN is connected to the gate of the transistor TR36 and one electrode of the capacitor CP. The source of the transistor TR36 is grounded. The drain and the source of the transistor TR37 are connected to the bus LBUS and the drain of the transistor TR36, respectively. The drain of the transistor TR38 is connected to the source of the transistor TR34. The source of the transistor TR38 is electrically connected to the bit line BL associated with the sense amplifier unit SAU.

For example, the power supply voltage VDD is applied to the source of the transistor TR30. For example, the ground voltage VSS is applied to the node SRC. Control signals BLX, HLL, XXL, BLC, and STB are input to the gates of the transistors TR31, TR32, TR33, TR34, and TR37, respectively. A control signal BLS is input to the gate of the transistor TR38. A clock signal CLK is input to the other electrode of the capacitor CP.

An input node and an output node of the inverter IV0 are connected to the nodes SLAT and SINV, respectively. An input node and an output node of the inverter IV1 are connected to the nodes SINV and SLAT, respectively. One end and the other end of the transistor TR40 are connected to the node SINV and the bus LBUS, respectively. A control signal STI is input to the gate of the transistor TR40. One end and the other end of the transistor TR41 are connected to the node SLAT and the bus LBUS, respectively. A control signal STL is input to the gate of the transistor TR41. The latch circuit SDL stores data at the node SLAT, and stores inverted data of the data stored at the node SLAT at the node SINV.

The circuit configurations of the latch circuits ADL, BDL, CDL, and XDL are the same or similar to that of the latch circuit SDL. For example, the latch circuit ADL stores data at a node ALAT and stores the inverted data at a node AINV. A control signal ATI is input to the gate of the transistor TR40 of the latch circuit ADL, and a control signal ATL is input to the gate of the transistor TR41 of the latch circuit ADL. The latch circuit BDL stores data at a node BLAT and stores the inverted data at a node BINV. A control signal BTI is input to the gate of the transistor TR40 of the latch circuit BDL, and a control signal BTL is input to the gate of the transistor TR41 of the latch circuit BDL. The same applies to the latch circuits CDL and XDL, so description thereof will be omitted.

Furthermore, the control signals BLX, HLL, XXL, BLC, STB, BLS, STI, and STL, and the clock signal CLK are each generated by, for example, the sequencer 14. The sense amplifier module 17 may have other circuit configurations. For example, the number of latch circuits in each sense amplifier unit SAU can be changed according to the number of bits stored in the memory cell transistor MT. The sense amplifier unit SAU may have an arithmetic circuit capable of executing a simple logical operation. In the read operation of each page, the sense amplifier module 17 can confirm (determine) the data stored in the memory cell transistor MT by appropriately executing arithmetic processing using a latch circuit.

### <1-3> Structure of Semiconductor Device

The structure of the semiconductor device 1 will be described. In the drawings referred to below, a three-dimensional Cartesian coordinate system is used. The X direction corresponds to the extension direction of the word lines WL. The Y direction corresponds to the extension direction of the bit lines BL. The Z direction corresponds to a direction perpendicular to the front surface of the substrate that is taken as a reference. In this specification, “upper and lower” are defined based on the direction along the Z direction, with the direction away from the substrate that is taken as a reference as the positive direction (upper). As the substrate that is taken as a reference, for example, the substrate disposed at the bottom in the drawing is used. The front surface of the substrate corresponds to the surface on which a transistor (CMOS circuit) is formed. The rear surface of the substrate corresponds to the surface opposite to the front surface.

### <1-3-1> Appearance of Semiconductor Device

The appearance of the semiconductor device 1 according to the embodiment will be described. The semiconductor device 1 according to the embodiment is formed by bonding three semiconductor circuit substrates, each having a semiconductor circuit formed thereon, and then separating the bonded semiconductor circuit substrates into individual chips. That is, the semiconductor device 1 according to the embodiment has a bonded surface formed by bonding the semiconductor substrates W1 and W2, and a bonded surface formed by bonding the semiconductor substrates W2 and W3. In the following, a case where the semiconductor substrate W3 is removed during the manufacturing process of the semiconductor device 1 will be described. Depending on the structure of the memory cell array 10, a part of the semiconductor substrate W3 may remain after bonding of the semiconductor substrates W2 and W3.

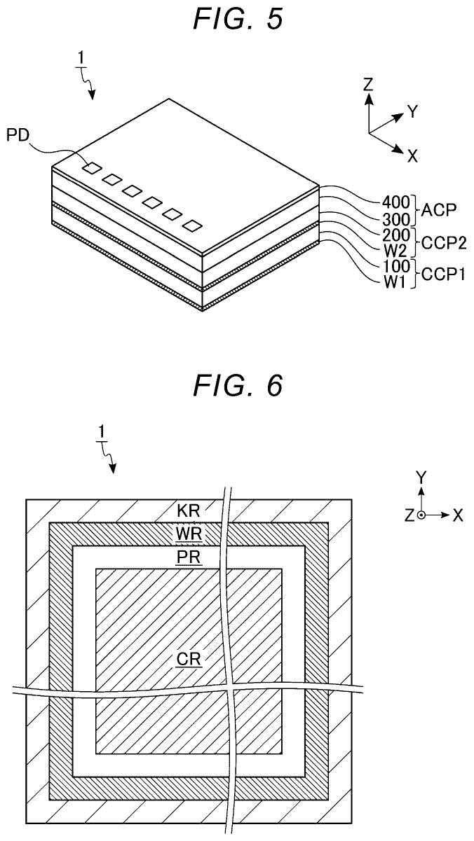

FIG. 5 is a perspective view diagram showing an example of the appearance of the semiconductor device 1 according to the embodiment. As shown in FIG. 5, the semiconductor device 1 has a structure in which, for example, the semiconductor substrate W1, a first CMOS layer 100, the semiconductor substrate W2, a second CMOS layer 200, a memory layer 300, and a wiring layer 400 are stacked in this order from the bottom.

The first CMOS layer 100 includes a CMOS circuit formed using the semiconductor substrate W1. The second CMOS layer 200 includes a CMOS circuit formed using the semiconductor substrate W2. A set including the first CMOS layer 100 and the second CMOS layer 200 includes, for example, the input/output circuit 11, the logic controller 12, the register circuit 13, the sequencer 14, the driver circuit 15, the row decoder module 16, and the sense amplifier module 17. The memory layer 300 includes the memory cell array 10 formed using the semiconductor substrate W3 (not shown). The wiring layer 400 includes, for example, a plurality of pads PD used for connecting the semiconductor device 1 and the memory controller 2. The pad PD is connected to the input/output circuit 11 and is exposed on the front surface of the semiconductor device 1. In the following, the semiconductor substrate W1 and the first CMOS layer 100 are collectively referred to as a “first CMOS chip CCP1”. The semiconductor substrate W2 and the second CMOS layer 200 are collectively referred to as a “second CMOS chip CCP2”. The memory layer 300 and the wiring layer 400 are collectively referred to as an “array chip ACP”.

Each of the semiconductor substrate W1, the semiconductor substrate W2, and the semiconductor substrate W3 is, for example, a silicon substrate. Each of the semiconductor substrates W1 and W2 has an impurity diffusion region according to the circuit design of the semiconductor device 1. The thickness of the semiconductor substrate W2 is, for example, thinner than the thickness of the semiconductor substrate W1. The semiconductor device 1 has a bonded surface between adjacent substrates. In the embodiment, the contact (boundary) portion between the first CMOS layer 100 and the semiconductor substrate W2 and the contact (boundary) portion between the second CMOS layer 200 and the memory layer 300 each correspond to the bonded surface. The bonded surface is a surface formed by bonding two wafers (substrates) together, and corresponds to the boundary portion between the two bonded substrates. A layer on which circuits such as the first CMOS layer 100 are formed may be sandwiched between the two bonded substrates. In this specification, the process of bonding two substrates together is referred to as a “bonding process”.

### <1-3-2> Planar Layout of Semiconductor Device

FIG. 6 is a plan view diagram showing an example of a planar layout of the semiconductor device 1 according to the embodiment. As shown in FIG. 6, the semiconductor device 1 includes, for example, a core region CR, a peripheral region PR, a wall region WR, and a kerf region KR.

The core region CR is, for example, a rectangular region provided in the vicinity of the center of the semiconductor substrate W1. In the core region CR, for example, the memory cell array 10, the register circuit 13, the sequencer 14, the driver circuit 15, the row decoder module 16, the sense amplifier module 17, and the like are disposed.

The peripheral region PR is a rectangular ring-shaped region provided to surround the outer periphery of the core region CR. In the peripheral region PR, for example, the input/output circuit 11, the logic controller 12, and the like are disposed. In addition, in the peripheral region PR, for example, contacts for connecting wiring provided in the wiring layer 400 to circuits provided in the first CMOS layer 100, the second CMOS layer 200, and the memory layer 300, and the like are disposed.

The wall region WR is a rectangular ring-shaped region provided to surround the outer periphery of the peripheral region PR. At least one sealing portion ES (not shown) provided to surround the outer periphery of the peripheral region PR is disposed in the wall region WR. The sealing portion ES will be described in detail later.

The kerf region KR is a rectangular ring-shaped region provided to surround the outer periphery of the wall region WR. The kerf region KR is in contact with the outermost periphery of the semiconductor device 1. In the kerf region KR, for example, alignment marks used during the manufacture of the semiconductor device 1 are disposed.

### <1-3-3> Planar Layout of Memory Cell Array

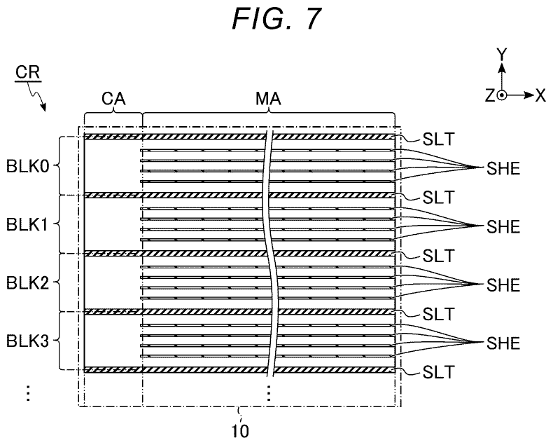

FIG. 7 is a plan view diagram showing an example of a planar layout of the memory cell array 10 in the core region CR of the semiconductor device 1 according to the embodiment. FIG. 7 shows an area corresponding to four blocks BLK0 to BLK3 in the memory cell array 10. As shown in FIG. 7, the memory cell array 10 includes, for example, a plurality of slits SLT and a plurality of slits SHE. Further, the memory cell array 10 includes, for example, a memory region MA and a contact region CA aligned in the X direction.

Each slit SLT has a portion extending along the X direction, and crosses the contact region CA and the memory region MA along the X direction. The plurality of slits SLT are aligned in the Y direction. Each slit SLT separates adjacent wirings (for example, word lines WL0 to WL7 and select gate lines SGD and SGS) via the slit SLT. In each slit SLT, a conductor having an insulating spacer provided on the side wall may be disposed with insulation from these wirings, or an insulator may be embedded. In the memory cell array 10, each of the areas separated by the slits SLT corresponds to one block BLK.

Each slit SHE has a portion extending along the X direction, and crosses the memory region MA along the X direction. The plurality of slits SHE are aligned in the Y direction. In this example, four slits SHE are disposed between each pair of slits SLT adjacent to each other in the Y direction. Each slit SHE has a structure in which, for example, an insulator is embedded. Each slit SHE separates adjacent wirings (at least the select gate lines SGD) via the slit SHE. In the memory cell array 10, each of the areas separated by the slits SLT and SHE corresponds to one string unit SU.

Furthermore, the planar layout of the memory cell array 10 in the semiconductor device 1 according to the embodiment may be other layouts. For example, the number of slits SHE disposed between two adjacent slits SLT can be designed to be any number. The number of string units SU in each block BLK can be changed based on the number of slits SHE disposed between two adjacent slits SLT.

### <1-3-4> Planar Layout of Memory Region

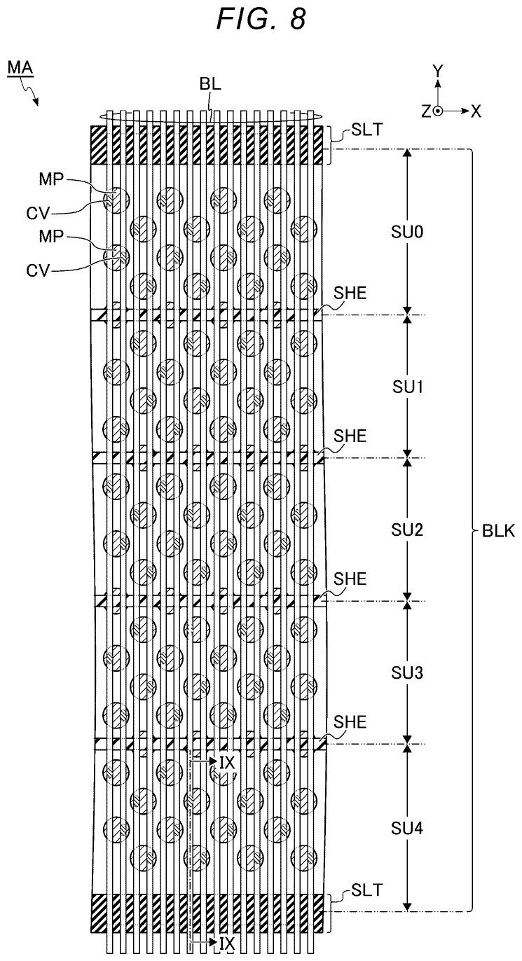

FIG. 8 is a plan view diagram showing an example of a planar layout of a memory region MA of the memory cell array 10 in the semiconductor device 1 according to the embodiment. FIG. 8 shows an area including one block BLK (string units SU0 to SU4). As shown in FIG. 8, the semiconductor device 1 includes, in the memory region MA, for example, a plurality of memory pillars MP, a plurality of contacts CV, and a plurality of bit lines BL.

Each memory pillar MP functions as one NAND string NS. The plurality of memory pillars MP are disposed in a staggered pattern of, for example, 24 rows in the area between two adjacent slits SLT. For example, counting from the top of the drawing, one slit SHE is disposed to overlap each of the fifth memory pillar MP, the tenth memory pillar MP, the fifteenth memory pillar MP, and the twentieth memory pillar MP.

Each bit line BL has a portion extending in the Y direction. The plurality of bit lines are aligned in the X direction. Each bit line BL is disposed to overlap at least one memory pillar MP, for each string unit SU. In this example, two bit lines BL are disposed to overlap one memory pillar MP. The memory pillar MP is electrically connected to one of the plurality of bit lines BL overlapped, via a contact CV. It is noted that the contacts CV between the memory pillars MP and the bit lines BL in contact with two different select gate lines SGD may be omitted.

Further, the planar layout of the memory region MA of the memory cell array 10 in the semiconductor device 1 according to the embodiment may be other layouts. For example, the number and arrangement of memory pillars MP, slits SHE, and the like disposed between two adjacent slits SLT can be changed as appropriate. The number of bit lines BL overlapping each memory pillar MP can be designed to be any number.

### <1-3-5> Cross-Sectional Structure of Memory Region

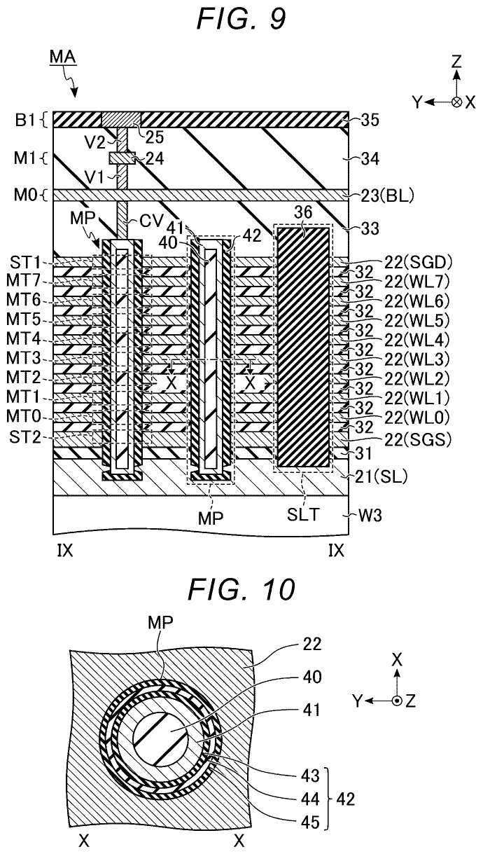

FIG. 9 is a cross-sectional view diagram taken along line IX-IX in FIG. 8, showing an example of a cross-sectional structure of the memory region MA of the memory cell array 10 in the semiconductor device 1 according to the embodiment. FIG. 9 shows an example of the structure of the memory cell array 10 formed on the semiconductor substrate W3 before being bonded to the semiconductor substrate W2, and shows coordinate axes based on the semiconductor substrate W3. As shown in FIG. 9, the memory cell array 10 includes, for example, conductive layers 21 to 25, insulating layers 31 to 35, an insulating member 36, and contacts CV, V1 and V2 in the memory region MA.

The conductive layer 21 is provided on the semiconductor substrate W3. The insulating layer 31 is provided on the conductive layer 21. On the insulating layer 31, the conductive layer 22 and the insulating layer 32 are provided alternately. That is, a plurality of conductive layers 22 are aligned in the Z direction. The number of layers of the conductive layer 22 corresponds to, for example, the number of layers of the stacked wirings (select gate line SGS, word line WL, and select gate line SGD). On the uppermost conductive layer 22, the insulating layer 33, the conductive layer 23, the insulating layer 34, and the insulating layer 35 are provided in this order. Each of the conductive layers 21 and 22 is formed, for example, in a plate shape spreading along the XY plane. The conductive layer 23 has, for example, a portion formed in a line shape extending in the Y direction. The conductive layer 21 is used as a source line SL. In this example, the ten conductive layers 22 aligned in the Z direction are used as, in order from the source line SL side, a select gate line SGS, word lines WL0 to WL7, and a select gate line SGD. The conductive layer 23 is used as a bit line BL. The conductive layer 21 contains, for example, polysilicon (Si). The conductive layer 22 contains, for example, tungsten (W). The conductive layer 23 contains, for example, copper (Cu). The conductive layer 23 is in the wiring layer M0.

The conductive layer 24 is provided above the conductive layer 23. The conductive layer 24 is a wiring that relays the connection between the bit line BL and the sense amplifier module 17. The conductive layer 23 and the conductive layer 24 are connected via the contact V1. The conductive layer 25 is provided above the conductive layer 24. The conductive layer 25 corresponds to the bonding pad BP used to bond the semiconductor substrate W2 and the semiconductor substrate W3. The conductive layer 24 and the conductive layer 25 are connected via the contact V2. The side surfaces of the conductive layer 24 and the contacts V1 and V2 are covered with the insulating layer 34. The insulating layer 34 may include a plurality of insulating films. The side surfaces of the conductive layer 25 are covered with the insulating layer 35. The memory cell array 10 may include a plurality of conductive layers 24 and a plurality of conductive layers 25. The conductive layer 24 contains, for example, copper. The conductive layer 24 is in the wiring layer M1. The conductive layer 25 contains, for example, copper. The insulating layer 35 and the conductive layer 25 are in a bonding layer B1.

The insulating member 36 has a portion formed in a plate shape extending along the XZ plane. The insulating member 36 separates the insulating layer 31 from the conductive layers 22 and insulating layers 32 that are provided alternately. In this example, the insulating member 36 is embedded in the slit SLT. In the slit SLT, a conductor having an insulating spacer provided on the side wall may be disposed to be insulated from each of the conductive layers 21 and 22.

Each memory pillar MP extends along the Z direction, penetrates the insulating layer 31 and the conductive layers 22 and insulating layers 32 provided alternately, and is connected to the conductive layer 21. Each memory pillar MP includes, for example, a core member 40, a semiconductor layer 41, and a stacked film 42. The core member 40 is an insulator extending along the Z direction. The semiconductor layer 41 covers the core member 40. A portion of the side surface of the semiconductor layer 41 is in contact with the conductive layer 21. In other words, the semiconductor layer 41 in the memory pillar MP and the conductive layer 21 (source line SL) are connected via the side surface of the memory pillar MP. The stacked film 42 covers the side surface and bottom surface of the semiconductor layer 41 except for the contact portion between the semiconductor layer 41 and the conductive layer 21. The associated semiconductor layer 41 (memory pillar MP) and the conductive layer 23 (bit line BL) are connected via the contact CV.

The portion where the conductive layer 22 used as the select gate line SGS and the memory pillar MP intersect functions as a select transistor ST2. The portion where the conductive layer 22 used as the word line WL and the memory pillar MP intersect functions as a memory cell transistor MT. The portion where the conductive layer 22 used as the select gate line SGD and the memory pillar MP intersect functions as a select transistor ST1. In each memory pillar MP, the semiconductor layer 41 is used as a channel (current path) for the memory cell transistors MT0 to MT7 and the select transistors ST1 and ST2 in the NAND string NS.

### <1-3-6> Cross-Sectional Structure of Memory Pillar

FIG. 10 is a cross-sectional view diagram taken along line X-X in FIG. 9, showing an example of a cross-sectional structure of the memory pillar MP in the semiconductor device 1 according to the embodiment. FIG. 10 shows a cross section including the memory pillar MP and the conductive layer 22 and parallel to the front surface of the semiconductor substrate W3. As shown in FIG. 10, the stacked film 42 includes, for example, a tunnel insulating film 43, an insulating film 44, and a block insulating film 45. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 22 surrounds the side surface of the block insulating film 45. Each of the tunnel insulating film 43 and the block insulating film 45 contains, for example, silicon oxide (SiO₂). The insulating film 44 is used as a charge storage layer of the memory cell transistor MT. The insulating film 44 contains, for example, silicon nitride (SiN).

<1-3-7> Planar Layout of contact region

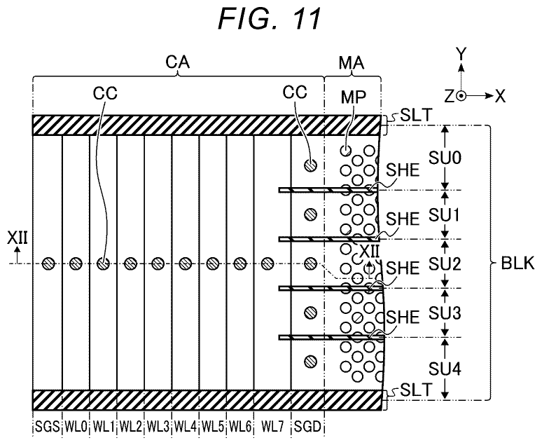

FIG. 11 is a plan view diagram showing an example of a planar layout of the contact region CA of the memory cell array 10 in the semiconductor device 1 according to the embodiment. FIG. 11 also shows a memory region MA in the vicinity of the contact region CA. As shown in FIG. 11, in the contact region CA, for example, the end of each of the select gate line SGS, the word lines WL0 to WL7, and the select gate line SGD has a terrace portion.

The terrace portion corresponds to a portion of the stacked wiring that does not overlap with an upper wiring layer (i.e., conductive layer). The structure formed by a plurality of terrace portions is similar to a step, a terrace, a rimstone, or the like. In this example, a staircase structure having steps in the X direction is formed by an end of the select gate line SGS, an end of each of the word lines WL0 to WL7, and an end of the select gate line SGD. In other words, steps are formed between the select gate line SGS and the word line WL0, between the word line WL0 and the word line WL1, . . . , between the word line WL6 and the word line WL7, and between the word line WL7 and the select gate line SGD, respectively.

The semiconductor device 1 also includes a plurality of contacts CC in the block BLK of the contact region CA. The contacts CC are members used for connection between the row decoder module 16 and the stacked wiring. Each contact CC is connected to one of the terrace portions of the stacked wirings provided in the memory cell array 10 in the block BLK, that is, the plurality of conductive layers 22 (select gate line SGS, word lines WL0 to WL7, and select gate line SGD).

Although the case where the contact CC is connected to the terrace portion formed in the contact region CA has been described, the present disclosure is not limited to this. Even when a terrace portion is not provided in the contact region CA, the semiconductor device 1 only needs to have a structure in which a set including a certain contact CC and an associated wiring are electrically connected without short-circuiting with other wiring.

### <1-3-8> Cross-Sectional Structure of Contact Region

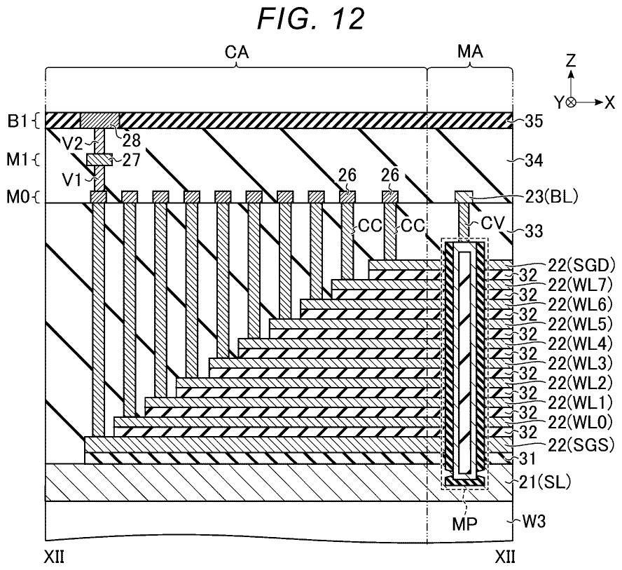

FIG. 12 is a cross-sectional view diagram taken along line XII-XII in FIG. 11, showing an example of a cross-sectional structure of the contact region CA of the memory cell array 10 in the semiconductor device 1 according to the embodiment. FIG. 12 shows a structure in the contact region CA of the memory cell array 10 formed on the semiconductor substrate W3 before the bonding process, and a memory region MA in the vicinity of the contact region CA. As shown in FIG. 12, the ends of the plurality of conductive layers 22 are provided in a stepped shape and are covered with the insulating layers 33. In the contact region CA, the insulating layers 34 and 35 are stacked on the insulating layer 33. Further, the semiconductor device 1 includes, for example, a plurality of contacts CC, a plurality of contacts V1 and V2, and a plurality of conductive layers 26, 27, and 28 in the contact region CA.

The plurality of contacts CC are provided on the terrace portions of the select gate line SGS, the word lines WL0 to WL7, and the select gate line SGD, respectively. Each contact CC penetrates the insulating layer 33. One conductive layer 26 is provided on each of the plurality of contacts CC. The contact V1 is provided on each conductive layer 26. FIG. 12 shows only the contact V1 that corresponds to the select gate line SGS, among the plurality of contacts V1. The conductive layer 27 is provided on the contact V1. The contact V2 is provided on the conductive layer 27. The conductive layers 26 and 27 and the plurality of contacts V1 and V2 are covered with the insulating layer 34. On the contact V2, the conductive layer 28 is provided to penetrate the insulating layer 35. The conductive layer 28 corresponds to the bonding pad BP used to bond the semiconductor substrate W2 and the semiconductor substrate W3. The conductive layer 26 contains, for example, copper. The conductive layer 26 is in the wiring layer M0. The conductive layer 27 contains, for example, copper. The conductive layer 27 is in the wiring layer M1. The conductive layer 28 contains, for example, copper. The conductive layer 28 is in the bonding layer B1.

A set including the conductive layers 26, 27, and 28 and the contacts CC, V1, and V2 described above corresponds to wirings and contacts for connecting any of the plurality of conductive layers 22 to the row decoder module 16. Although not shown, each of the plurality of conductive layers 22 other than the select gate line SGS is similarly connected to the row decoder module 16 via the set including the conductive layers 26, 27, and 28 and the contacts CC, V1, and V2.

### <1-3-9> Cross-Sectional Structure of Semiconductor Device

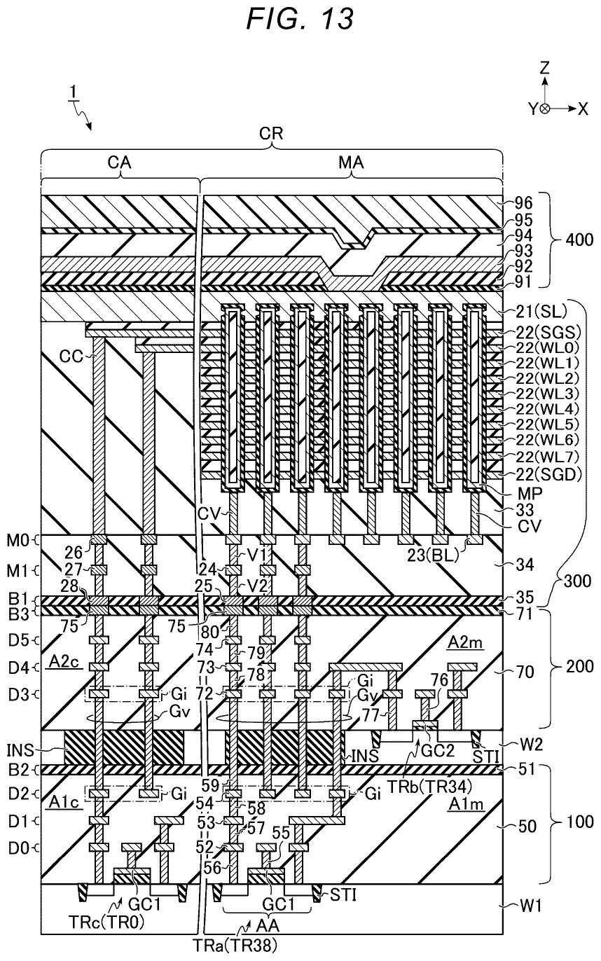

FIG. 13 is a cross-sectional view diagram showing an example of a cross-sectional structure of the core region CR of the semiconductor device 1 according to the embodiment. FIG. 13 shows a cross section including the memory region MA and contact region CA in the core region CR of the semiconductor device 1, and indicates coordinate axes based on the semiconductor substrate W1. FIG. 13 shows the state after the semiconductor substrate W3 is removed. As shown in FIG. 13, the semiconductor device 1 has a structure in which the structure of the memory region MA shown in FIG. 9 is inverted vertically, and a structure in which the structure of the contact region CA shown in FIG. 12 is inverted vertically, corresponding to the memory layer 300. The semiconductor device 1 includes, corresponding to the first CMOS layer 100, insulating layers 50 and 51, conductive layers GC1 and 52 to 54, and contacts 55 to 59. The semiconductor device 1 includes, corresponding to the second CMOS layer 200, insulating layers 70 and 71, conductive layers GC2 and 72 to 75, and contacts 59 and 76 to 80. The semiconductor device 1 includes, corresponding to the wiring layer 400, an insulating layer 91, an insulating layer 92, a conductive layer 93, an insulating layer 94, an insulating layer 95, and an insulating layer 96.

In the following, an area corresponding to the memory region MA of the first CMOS chip CCP1 will be referred to as “area A1m”. An area corresponding to the contact region CA of the first CMOS chip CCP1 is referred to as an “area A1c”. An area corresponding to the memory region MA of the second CMOS chip CCP2 is referred to as an “area A2m”. An area corresponding to the contact region CA of the second CMOS chip CCP2 is referred to as an “area A2c”.

The insulating layer 50 is provided on the semiconductor substrate W1. The insulating layer 50 covers the circuits (for example, the conductive layers GC1 and 52 to 54, and the contacts 55 to 59) provided on the semiconductor substrate W1. The insulating layer 50 may include a plurality of insulating layers. Further, the insulating layer 50 includes wiring layers D0, D1, and D2 in this order from the semiconductor substrate W1 side. Wirings for the first CMOS layer 100 are provided in the wiring layers D0, D1, and D2. The insulating layer 51 is provided on the insulating layer 50. The insulating layer 51 is in contact with the rear surface of the semiconductor substrate W2. The boundary portion between the insulating layer 51 and the semiconductor substrate W2 corresponds to the bonded surface between the semiconductor substrate W1 and the semiconductor substrate W2 (the first CMOS chip CCP1 and the second CMOS chip CCP2). The insulating layer 51 contains, for example, silicon oxide. In the following, the layer including the insulating layer 51 will be referred to as a “bonding layer B2”.

The insulating layer 70 is provided on the semiconductor substrate W2. The insulating layer 70 covers the circuit (for example, the conductive layers GC2 and 72 to 74, and the contacts 59 and 76 to 80) provided on the semiconductor substrate W2. The insulating layer 70 may include a plurality of insulating layers. Further, the insulating layer 70 includes wiring layers D3, D4, and D5 in this order from the semiconductor substrate W1 side. Wirings for the second CMOS layer 200 are provided in the wiring layers D3, D4, and D5. Furthermore, the number of wiring layers in the second CMOS layer 200 may be different from the number of wiring layers in the first CMOS layer 100. The insulating layer 71 is provided on the insulating layer 70. The insulating layer 71 is in contact with the insulating layer 35 in the memory layer 300. The boundary between the insulating layer 71 and the insulating layer 35 corresponds to the bonded surface between the semiconductor substrate W2 and the semiconductor substrate W3 (the second CMOS chip CCP2 and the array chip ACP). The insulating layer 71 contains, for example, silicon oxide. In the following, the layer including the insulating layer 71 will be referred to as the “bonding layer B3”.

The conductive layer GC1 is provided on a gate insulating film provided on the semiconductor substrate W1. The contact 55 is provided on the conductive layer GC1. The two contacts 56 in the area A1m are connected to two impurity diffusion regions provided in the semiconductor substrate W1. For example, the two impurity diffusion regions correspond to the source and drain of the transistor TRa, respectively. Similarly, the two contacts 56 in the area A1c are connected to two impurity diffusion regions provided in the semiconductor substrate W1. For example, the two impurity diffusion regions correspond to the source and drain of the transistor TRc, respectively. The semiconductor substrate W1 is provided with shallow trench isolation (STI) as appropriate in accordance with the layout of the transistors. The STI is provided to electrically isolate the transistors from other elements. The STI (hereinafter also referred to as “insulating film region STI”) surrounds an active area AA of the transistor. The active area AA is the area in which the transistors are provided. The active area AA includes, for example, the gate insulating film, the conductive layer GC1, and two impurity diffusion regions. The insulating film region STI is in contact with the impurity diffusion region. The transistor TRa is in, for example, the sense amplifier module 17. The transistor TRa is, for example, an HV transistor (transistor TR38) in the sense amplifier unit SAU. The transistor TRc is in, for example, the row decoder module 16. The transistor TRc is, for example, an HV transistor (transistor TR0) in the row decoder RD. The row decoder RD is in the first CMOS chip CCP1.

The semiconductor substrate W1 and the transistors provided on the semiconductor substrate W1 are subjected to heat of about 1000° C. in an activation annealing process, which will be described below, during the manufacture of the semiconductor device 1. Therefore, in consideration of heat resistance, the thickness of the semiconductor substrate W1 is set to be thicker than the thickness of the semiconductor substrate W2. In addition, in consideration of heat resistance, for example, an HV transistor is disposed on the semiconductor substrate W1. The reason why the thickness of the semiconductor substrate W1 on which the HV transistor is provided is made relatively thick is that a depletion layer in the HV transistor spreads relatively easily. Furthermore, the transistors provided on the semiconductor substrate W1 may be LV transistors that can withstand the heat in the activation annealing process.

The conductive layer 52 is provided on each of the contacts 55 and 56. The conductive layer 52 is in the wiring layer D0. The conductive layer 53 is provided on the conductive layer 52 via the contact 57. The conductive layer 53 is in the wiring layer D1. The conductive layer 54 is provided on the conductive layer 53 via the contact 58. The conductive layer 54 is in the wiring layer D2. The conductive layers 52 to 54 are subjected to heat of about 1000° C. in an activation annealing process during manufacture. Therefore, the conductive layers 52 to 54 are made of a conductive material with a relatively high melting point. The conductive layers 52 to 54 contain, for example, tungsten. The contact 59 is provided on the conductive layer 54. The contact 59 is provided to penetrate the semiconductor substrate W2 and the insulating layer 51. The contact 59 and the semiconductor substrate W2 are insulated from each other by an insulating film region INS. That is, the semiconductor substrate W2 includes the insulating film region INS penetrating the semiconductor substrate W2. The semiconductor substrate W2 includes a plurality of insulating film regions INS. Furthermore, the thickness of the insulating film region STI is thinner than the thickness of the insulating film region INS. The contacts 59 correspond to through vias. A plurality of contacts 59 penetrate the insulating film region INS. That is, the plurality of contacts 59 penetrate the insulating film region INS provided in the semiconductor substrate W2. The contacts 59 contain, for example, tungsten or copper. The insulating film region INS includes, for example, silicon oxide or silicon nitride. In the following, the contact 59 will be referred to as a “through via 59”. A plurality of through vias 59 penetrating one insulating film region INS is referred to as a “through via group Gv”. A plurality of wirings each provided on the same layer and in contact with the through via group Gv is referred to as a “wiring group Gi”.

The conductive layer GC2 is provided on a gate insulating film provided on the semiconductor substrate W2. The contact 76 is provided on the conductive layer GC2. The two contacts 77 in the area A2m are connected to two impurity diffusion regions provided in the semiconductor substrate W2. For example, the two impurity diffusion regions correspond to the source and drain of the transistor TRb, respectively. In the semiconductor substrate W2, STI is appropriately provided according to the layout of the transistors. The transistor TRb is in, for example, the sense amplifier module 17. The transistor TRb is, for example, an LV transistor (transistor TR34) in the sense amplifier unit SAU. LV transistors operate faster than HV transistors. The sense amplifier unit SAU is in the first CMOS chip CCP1 and the second CMOS chip CCP2.

In order to thin the semiconductor device 1, the thickness of the semiconductor substrate W2 is set to be thinner than the thickness of the semiconductor substrate W1. Therefore, for example, an LV transistor is disposed on the semiconductor substrate W2. Furthermore, the transistor provided on the semiconductor substrate W2 may be, for example, a MOS transistor with a lower breakdown voltage than an LV transistor (hereinafter also referred to as a “Very-Low-Voltage (VLV) transistor”), or a MOS transistor with a high breakdown voltage that can operate even when the thickness of the semiconductor substrate W2 is relatively thin (hereinafter also referred to as an “High-Voltage-Negative (HVN) transistor”). The HVN transistor is an N-type HV transistor.

The gate lengths of the transistors TRa and TRc, which are HV transistors, are longer than the gate length of the transistor TRb, which is an LV transistor. The magnitude relationship between the gate lengths of the VLV transistor, the LV transistor, and the HV transistor is, for example, VLV transistor <LV transistor <HV transistor. The film thickness of the gate insulating film of the transistors TRa and TRc is thicker than the film thickness of the gate insulating film of the transistor TRb. The magnitude relationship between the film thicknesses of the gate insulating films of the VLV transistor, the LV transistor, and the HV transistor is VLV transistor <LV transistor <HV transistor.

The conductive layer 72 is provided over each of the contacts 76 and 77 and the through vias 59. The conductive layer 72 is in the wiring layer D3. The position of the upper surface of each of the plurality of through vias 59 penetrating the insulating film region INS is the same as the position of the upper surfaces of the contacts 76 and 77. A conductive layer 73 is provided on the conductive layer 72 via a contact 78. The conductive layer 73 is in the wiring layer D4. The conductive layer 73 may be provided in a current path between the contact 77 and the through via 59, or may be provided in a current path between the through via 59 and the bonding pad BP. In the example of FIG. 13, the source or drain of the transistor TRa is electrically connected to the source or drain of the transistor TRb via the contacts 56 to 58, the through via 59, the contacts 78 and 77, and the conductive layers 52 to 54, 72, and 73. A conductive layer 74 is provided on the conductive layer 73 via a contact 79. The conductive layer 74 is in the wiring layer D5. The conductive layers 72 to 74 contain, for example, copper. A conductive layer 75 is provided on the conductive layer 74 via a contact 80. The conductive layer 75 is in the bonding layer B3. The conductive layer 75 corresponds to the bonding pad BP used to bond the semiconductor substrate W2 and the semiconductor substrate W3. The conductive layer 75 contains, for example, copper.

With the above structure, in the memory region MA and the contact region CA, the first CMOS chip CCP1 and the second CMOS chip CCP2 are electrically connected to each other via the through via group Gv penetrating the insulating film region INS.

In the memory region MA, a through via group Gv including the plurality of through vias 59 penetrating the insulating film region INS is connected to a wiring group Gi including a plurality of conductive layers 54 (wirings) provided in the wiring layer D2. One of the plurality of conductive layers 54 in the wiring group Gi of the wiring layer D2 is electrically connected to a conductive layer 52 (wiring) electrically connected to one of the source or drain of the transistor TRa. Another one of the plurality of conductive layers 54 in the wiring group Gi of the wiring layer D2 is electrically connected to a conductive layer 52 (wiring) electrically connected to the other of the source or drain of the transistor TRa. Further, a through via group Gv including the plurality of through vias 59 penetrating the insulating film region INS is connected to a wiring group Gi including a plurality of conductive layers 72 provided in the wiring layer D3. Of the plurality of conductive layers 72 in the wiring group Gi of the wiring layer D3, the conductive layer 72 electrically connected to the other of the source or drain of the transistor TRa via the conductive layers 52 and 54, as well as the through via 59, is electrically connected to a conductive layer 72 (wiring) electrically connected to one of the source or drain of the transistor TRb.

In the contact region CA, a through via group Gv including the plurality of through vias 59 penetrating the insulating film region INS is connected to a wiring group Gi including a plurality of conductive layers 54 (wirings) provided in the wiring layer D2. One of the plurality of conductive layers 54 in the wiring group Gi of the wiring layer D2 is electrically connected to a conductive layer 52 (wiring) electrically connected to one of the source or drain of the transistor TRc. Further, a through via group Gv including the plurality of through vias 59 penetrating the insulating film region INS is connected to a wiring group Gi including a plurality of conductive layers 72 provided in the wiring layer D3.

In the memory region MA, the conductive layer 25 is in contact with and opposed to the conductive layer 75. The conductive layer 25 is connected to the associated conductive layer 23 (bit line BL) via contacts V1 and V2 and the conductive layer 24. Thus, the conductive layer 23 (bit line BL) is connected to the transistor TRa provided on the semiconductor substrate W1 via the contacts V1, V2, 78 to 80, and 56 to 58, the through via 59, and the conductive layers 24, 25, 72 to 75, and 52 to 54. Similarly, each of the other conductive layers 23 is connected to the other transistors provided on the semiconductor substrate W1.

In the contact region CA, the conductive layer 28 is in contact with and opposed to the conductive layer 75. The conductive layer 28 is connected to an associated conductive layer 22 (for example, select gate line SGS) via contacts V1, V2, and CC, and conductive layers 26 and 27. Thus, the conductive layer 22 (for example, the select gate line SGS) is connected to the transistor TRc provided on the semiconductor substrate W1 via the contacts CC, V1, V2, 78 to 80, and 56 to 58, the through via 59, and the conductive layers 26 to 28, 72 to 75, and 52 to 54. Similarly, each of the other conductive layers 22 is connected to the other transistors provided the semiconductor substrate W1.

On the conductive layer 21, an insulating layer 91, an insulating layer 92, a conductive layer 93, an insulating layer 94, an insulating layer 95, and an insulating layer 96 are provided in this order. A portion of the conductive layer 93 penetrates the insulating layers 91 and 92. The conductive layer 93 may have a portion in contact with the conductive layer 21. Each of the insulating layers 91, 92, and 94 contains, for example, silicon oxide. The insulating layer 95 contains, for example, silicon nitride. The insulating layer 96 contains, for example, polyimide.

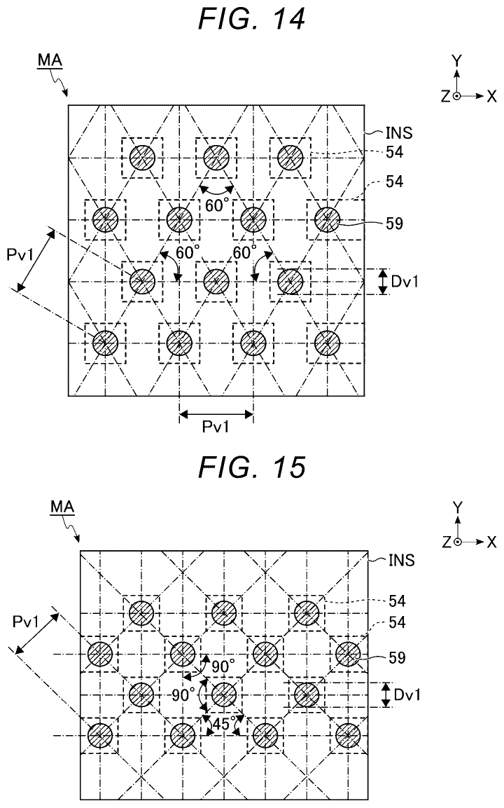

FIG. 14 is a plan view diagram showing an example of a planar layout of the through vias 59 in the memory region MA of the semiconductor device 1. FIG. 14 shows an example in which 14 through vias 59 penetrate the insulating film region INS, and the conductive layers 54 connected to the through vias 59 are indicated by dotted lines. As shown in FIG. 14, the through via 59 has, for example, a circular cross-sectional shape in the XY plane (a cross section parallel to the front surface of the semiconductor substrate W1). When the diameter of the through via 59 is “diameter Dv1” and the pitch (distance) between two adjacent through vias 59 is “pitch Pv1,” a plurality of through vias 59 having diameter Dv1 are disposed in a 60° staggered pattern at pitch Pv1 (60° staggered arrangement). In other words, each of the plurality of through vias 59 is disposed at each vertex of an equilateral triangle. This arrangement corresponds to a honeycomb structure. Furthermore, the plurality of through vias 59 may be disposed, for example, in a square or in a 45° staggered pattern.

FIG. 15 is a plan view diagram showing another example of a planar layout of the through vias 59 in the memory region MA of the semiconductor device 1. As shown in FIG. 15, a plurality of through vias 59 having a diameter Dv1 are disposed in a 45° staggered pattern at a pitch Pv1 (45° staggered arrangement). In other words, each of the plurality of through vias 59 is disposed at each vertex of a square and at the intersection of the diagonal of the square.

In the memory region MA, the insulating film region INS formed on the semiconductor substrate W2 is formed in, for example, a region in which the sense amplifier module 17 is disposed (hereinafter, referred to as the “sense amplifier region”). In the sense amplifier region, the plurality of through vias 59 are connected to corresponding bit lines BL. The plurality of through vias 59 are each drawn out and connected to a corresponding HV transistor of the sense amplifier unit SAU. In addition, the HV transistor is connected to the LV transistor. Through vias 59 for connecting the HV transistor and the LV transistor are also provided in the insulating film region INS. Therefore, the plurality of through vias 59 are connected to different conductive layers 54 (wirings), respectively. Furthermore, since the number of through vias 59 is relatively large, the plurality of through vias 59 are disposed as densely as possible in the insulating film region INS. In order to arrange the maximum number of vias in the minimum area, the plurality of through vias 59 are preferably disposed in a manner corresponding to a honeycomb structure.

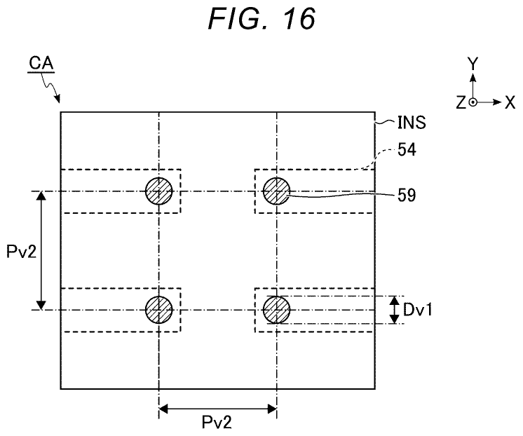

FIG. 16 is a plan view diagram showing an example of a planar layout of the through vias 59 in the contact region CA of the semiconductor device 1. FIG. 16 shows an example in which four through vias penetrate the insulating film region INS, and the conductive layers 54 connected to the through vias 59 are indicated by dotted lines. As shown in FIG. 16, the through via 59 has, for example, a circular cross-sectional shape in the XY plane. When the diameter of the through via 59 is “diameter Dv1” and the pitch between two adjacent through vias 59 is “pitch Pv2,” a plurality of through vias 59 having diameter Dv1 are disposed in a square at the pitch Pv2. That is, the arrangement of the through via group Gv penetrating the insulating film region INS formed in the contact region CA is different from the arrangement of the through via group Gv penetrating the insulating film region INS formed in the memory region MA. Furthermore, the plurality of through vias 59 may be disposed, for example, in a 60° staggered pattern or in a 45° staggered pattern.

In the contact region CA, the insulating film region INS formed in the semiconductor substrate W2 is formed in, for example, an area in which the row decoder module 16 is disposed (hereinafter, referred to as the “row decoder region”). In the row decoder region, the plurality of through vias 59 are connected to corresponding word lines WL. The plurality of through vias 59 are each drawn out and connected to a corresponding transistor of the row decoder RD. Therefore, the plurality of through vias 59 are connected to different conductive layers 54 (wirings), respectively. Furthermore, although the number of through vias 59 is relatively large, a relatively high voltage is applied to the row decoder RD, so the pitch between two adjacent through vias 59 is set to a distance that ensures the breakdown voltage between two adjacent through vias 59. Therefore, the pitch Pv2 is larger than the pitch Pv1. That is, the through via group Gv penetrating the insulating film region INS formed in the contact region CA are disposed at a pitch different from the through via group Gv penetrating the insulating film region INS formed in the memory region MA.

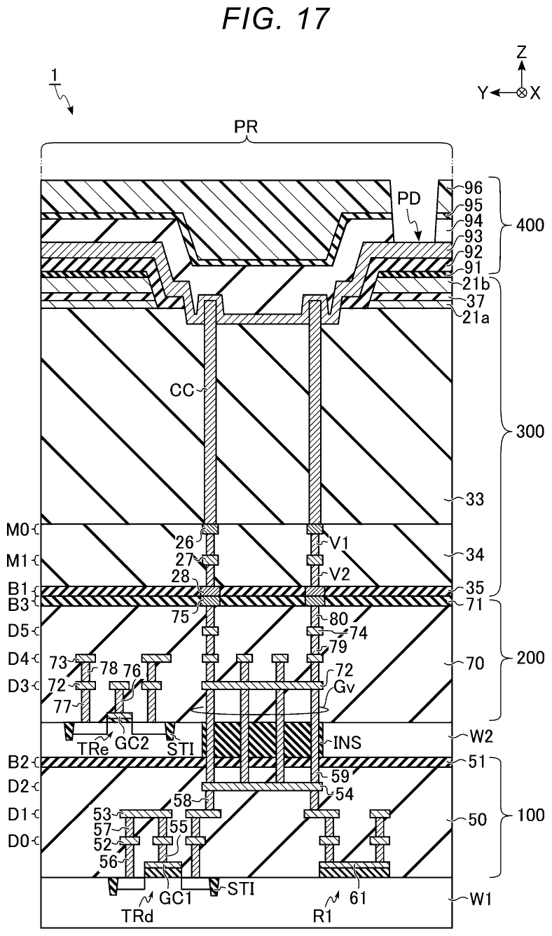

FIG. 17 is a cross-sectional view diagram showing an example of a cross-sectional structure of the peripheral region PR of the semiconductor device 1 according to the embodiment. FIG. 17 shows a cross section including the peripheral region PR of the semiconductor device 1, and indicates coordinate axes based on the semiconductor substrate W1. FIG. 17 shows the state after the semiconductor substrate W3 is removed.

In the peripheral region PR, the first CMOS layer 100 includes, similarly to the core region CR, insulating layers 50 and 51, conductive layers GC1 and 52 to 54, contacts 55 to 58, and a through via 59. The first CMOS layer 100 further includes a conductive layer 61. The semiconductor substrate W1 includes, similarly to the core region CR, two impurity diffusion regions provided in areas corresponding to the source and drain of the transistor, and an insulating film region STI provided according to the layout of the transistor.

The conductive layer GC1 is provided on a gate insulating film provided on the semiconductor substrate W1. The contact 55 is provided on the conductive layer GC1. The two contacts 56 are connected to two impurity diffusion regions provided in the semiconductor substrate W1. For example, of the two impurity diffusion regions, the impurity diffusion region on the left side of the drawing corresponds to the drain of a transistor TRd, and the impurity diffusion region on the right side of the drawing corresponds to the source. A plurality of conductive layers 52 are provided on the contact 55 connected to the gate, the contact 56 connected to the drain, and the contact 56 connected to the source, respectively. The plurality of contacts 57 are provided on the plurality of conductive layers 52, respectively. The plurality of conductive layers 53 are provided on the plurality of contacts 57, respectively. The conductive layer 53 provided on the contact 57 electrically connected to the gate and the contact 57 electrically connected to the drain is configured as one conductive layer 53. That is, the transistor TRd is, for example, a diode-connected transistor in which the gate and the drain are connected to each other. The conductive layer 53 electrically connected to the source is connected to the conductive layer 54 via the contact 58.

The conductive layer 61 is provided on an insulating film provided on the semiconductor substrate W1. The conductive layer 61 is, for example, a resistor element R1. The conductive layer 61 contains, for example, polysilicon. Two contacts 55 are provided on both ends of the conductive layer 61, respectively. The plurality of conductive layers 52 are provided on the plurality of contacts 55, respectively. The plurality of contacts 57 are provided on the plurality of conductive layers 52, respectively. The plurality of conductive layers 53 are provided on the plurality of contacts 57, respectively. The conductive layer 53 electrically connected to one end of the resistor element R1 is connected to the conductive layer 54 via the contact 58. The conductive layer 54 provided on the contact 58 electrically connected to the source of the transistor TRd and the contact 58 electrically connected to one end of the resistor element R1 is configured as one conductive layer 54. Furthermore, the resistor element R1 may be provided in the second CMOS layer 200.

In the peripheral region PR, the second CMOS layer 200 includes, similarly to the core region CR, insulating layers 70 and 71, conductive layers GC2 and 72 to 75, a through via 59, and contacts 76 to 80. The semiconductor substrate W2, similarly to the core region CR, includes an insulating film region INS penetrated by a plurality of through vias 59, two impurity diffusion regions provided in areas corresponding to the source and drain of the transistor, and an insulating film region STI provided according to the layout of the transistor. The conductive layer 74 is connected to a transistor TRe provided on the semiconductor substrate W2 via, for example, the contact 79 (not shown), the contacts 77 and 78, and the conductive layers 72 and 73. The transistor TRe is in the input/output circuit 11, for example. The transistor TRe is, for example, an LV transistor. Furthermore, the transistor TRe may be, for example, a VLV transistor or a HVN transistor. The conductive layer 72 provided on the plurality of through vias 59 penetrating the insulating film region INS is configured with one conductive layer 72. Of the plurality of conductive layers 73 provided via the contacts 78 on the conductive layer 72 connected to the plurality of through vias 59, the conductive layer 73 on the left side of the drawing and the conductive layer 73 on the right side of the drawing are connected to the conductive layer 75 (bonding pad BP) via the contact 79, the conductive layer 74, and the contact 80.

With the above structure, in the peripheral region PR, the first CMOS chip CCP1 and the second CMOS chip CCP2 are electrically connected to each other via the through via group Gv penetrating the insulating film region INS. The through via group Gv including the plurality of through vias 59 penetrating the insulating film region INS is connected to one conductive layer 54 (wiring) provided in the wiring layer D2. Further, the through via group Gv including the plurality of through vias 59 penetrating the insulating film region INS is connected to one conductive layer 72 (wiring) provided in the wiring layer D3.

In the peripheral region PR, the memory layer 300 includes, similarly to the core region CR, insulating layers 33 to 35, conductive layers 21 and 26 to 28, and contacts CC, V1, and V2. Further, the memory layer 300 includes a sacrificial member 37. The conductive layer 21 includes a conductive layer 21a and a conductive layer 21b. The sacrificial member 37 is provided between the conductive layer 21a and the conductive layer 21b.

A set including the conductive layer 21a, the sacrificial member 37, and the conductive layer 21b is provided at the same height as the conductive layer 21. Specifically, the height of the lower surface of the conductive layer 21a is aligned with the height of the lower surface of the conductive layer 21 (source line SL). The height of the upper surface of the conductive layer 21b is aligned with the height of the upper surface of the conductive layer 21 (source line SL). The conductive layer 21 in the core region CR corresponds to a structure in which the conductive layer 21a, the sacrificial member 37, and the conductive layer 21b are stacked, and then the sacrificial member 37 is replaced with a conductor. That is, the height of the sacrificial member 37 is the same as the height at which the conductive layer 21 and the semiconductor layer 41 in each memory pillar MP are connected. Each of the conductive layers 21a and 21b contains, for example, polysilicon. The sacrificial member 37 contains, for example, silicon nitride.

A plurality of contacts CC are provided on the conductive layer 26. The upper portion of the contact CC reaches the height of at least the conductive layer 21.

In the peripheral region PR, the wiring layer 400 includes, similarly to the core region CR, an insulating layer 91, an insulating layer 92, a conductive layer 93, an insulating layer 94, an insulating layer 95, and an insulating layer 96.

A portion of the conductive layer 93 penetrates the conductive layer 21a, the sacrificial member 37, the conductive layer 21b, and the insulating layers 91 and 92. The conductive layer 93 may have a portion in contact with the contact CC. The upper portion of the contact CC is covered with the conductive layer 93 and is electrically connected to the conductive layer 93. The conductive layer 93 is insulated from the conductive layers 21a and 21b by the insulating layer 92. A portion of the upper portion of the conductive layer 93 is not covered with the insulating layers 94 to 96. This portion functions as a pad PD. Thus, the pad PD is connected to the transistors and resistor elements provided on the semiconductor substrate W1 via the contacts CC, V1, V2, 78 to 80, and 56 to 58, the through via 59, and the conductive layers 26 to 28, 72 to 75, and 52 to 54. Furthermore, the pad PD is connected to transistors provided on the semiconductor substrate W2 via the contacts CC, V1, V2, and 77 to 80, and the conductive layers 26 to 28, and 72 to 75.

Furthermore, the pads PD of the semiconductor device 1 can be connected to the pads PD of another semiconductor device 1 by wire bonding. In a similar manner, three or more semiconductor devices 1 can be connected.

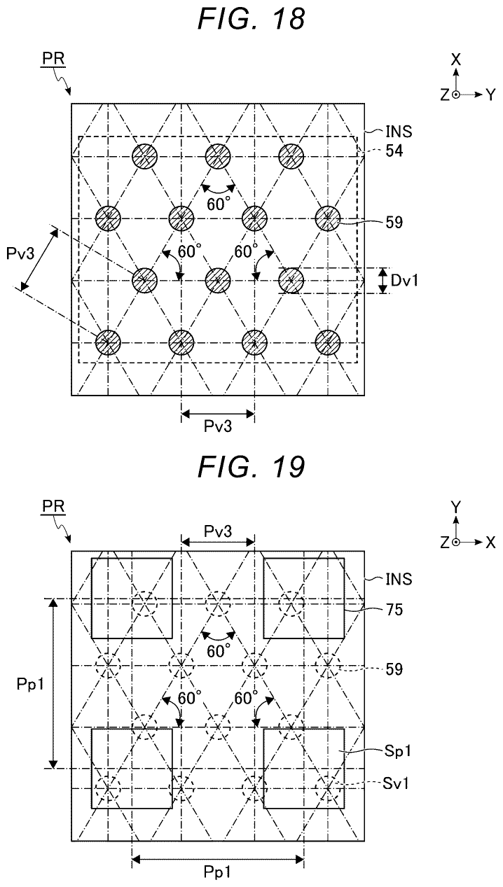

FIG. 18 is a plan view diagram showing an example of a planar layout of the through vias 59 in the peripheral region PR of the semiconductor device 1. FIG. 18 shows an example in which 14 through vias 59 penetrate the insulating film region INS, and the conductive layers 54 connected to the through vias 59 are indicated by dotted lines. As shown in FIG. 18, the through via 59 has, for example, a circular cross-sectional shape in the XY plane. When the diameter of the through via 59 is “diameter Dv1” and the pitch between two adjacent through vias 59 is “pitch Pv3,” a plurality of through vias 59 having diameter Dv1 are disposed in a 60° staggered pattern at pitch Pv3. This arrangement corresponds to a honeycomb structure. Furthermore, the plurality of through vias 59 may be disposed, for example, in a square or in a 45° staggered pattern.

FIG. 19 is a plan view diagram showing an example of a planar layout of the bonding pad BP (the conductive layer 75) in the peripheral region PR of the semiconductor device 1. In FIG. 19, four conductive layers 75 are shown, and the through vias 59, shown in FIG. 18, are shown in dotted lines. As shown in FIG. 19, the conductive layer 75 has, for example, a rectangular cross-sectional shape in the XY plane. When the pitch between two adjacent conductive layers 75 is “pitch Pp1,” a plurality of conductive layers 75 are disposed in a square at pitch Pp1. The pitch Pp1 of the conductive layers 75 is larger than the pitch Pv3 of the through vias 59. Furthermore, assuming that the cross-sectional area of the conductive layer 75 in the XY plane is “Sp1” and the cross-sectional area of the through via 59 in the XY plane is “Sv1”, the cross-sectional area Sp1 of the conductive layer 75 is larger than the cross-sectional area Sv1 of the through via 59 in the XY plane.

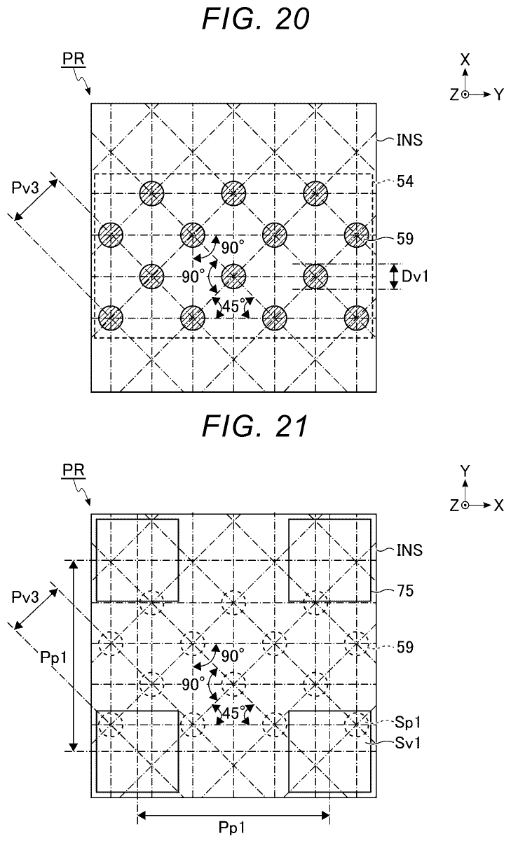

FIG. 20 is a plan view diagram showing another example of a planar layout of the through vias 59 in the peripheral region PR of the semiconductor device 1. As shown in FIG. 20, a plurality of through vias 59 having a diameter Dv1 are disposed in a 45° staggered pattern at a pitch Pv3.

FIG. 21 is a plan view diagram showing another example of a planar layout of the bonding pad BP (the conductive layer 75) in the peripheral region PR of the semiconductor device 1. In FIG. 21, four conductive layers 75 are shown, and the through vias 59, shown in FIG. 20, are shown in dotted lines. As shown in FIG. 21, the pitch Pp1 of the conductive layers 75 is larger than the pitch Pv3 of the through vias 59. Further, the area Sp1 of the conductive layer 75 is larger than the area Sv1 of the through via 59.

In the peripheral region PR, the insulating film region INS formed on the semiconductor substrate W2 is formed in, for example, a region in which the input/output circuit 11 is disposed (hereinafter, referred to as an “input/output circuit region”). In the input/output circuit region, a plurality of through vias 59 are connected to pads PD. The plurality of through vias 59 are each drawn out and connected to transistors in the input/output circuit 11 (transistors formed on the semiconductor substrate W1 and transistors formed on the semiconductor substrate W2). It is preferable that the resistance of the wiring path connected to the pad PD is as low as possible. Therefore, the plurality of through vias 59 are connected to one conductive layer 54 (wiring) and one conductive layer 72 (wiring). Furthermore, since the number of through vias 59 is relatively large, the plurality of through vias 59 are disposed as densely as possible in the insulating film region INS. Therefore, the pitch Pv3 is smaller than the pitch Pv2. Furthermore, the pitch Pv3 may be equal to the pitch Pv1, may be smaller than the pitch Pv1, or may be larger than the pitch Pv1. In order to arrange the maximum number of vias in the minimum area, the plurality of through vias 59 are preferably arranged in a manner corresponding to a honeycomb structure.

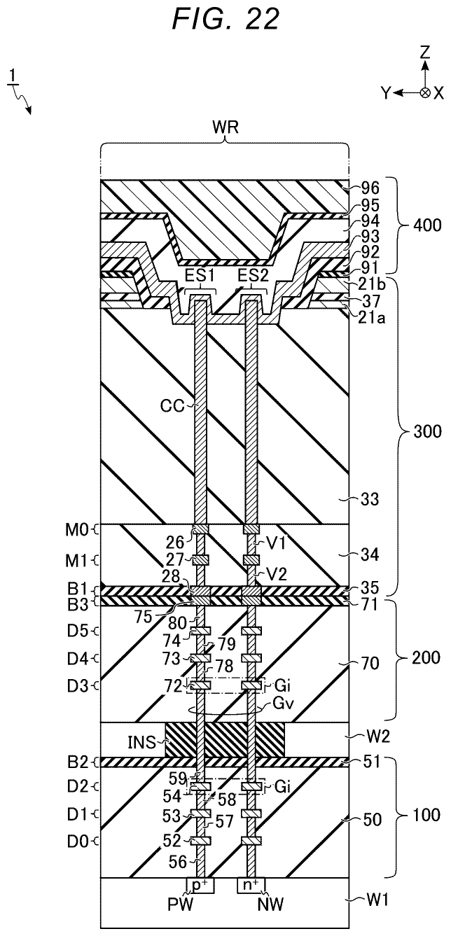

FIG. 22 is a cross-sectional view diagram showing an example of a cross-sectional structure of the wall region WR of the semiconductor device 1 according to the embodiment. FIG. 22 shows a cross section including the wall region WR of the semiconductor device 1, and indicates coordinate axes based on the semiconductor substrate W1. Furthermore, FIG. 22 shows the state after the semiconductor substrate W3 is removed.

In the wall region WR, the first CMOS layer 100 includes, similarly to the core region CR, insulating layers 50 and 51, conductive layers 52 to 54, contacts 56 to 58, and a through via 59. The semiconductor substrate W1 includes a P-type well region PW and an N-type well region NW. The P-type well region PW is a P-type impurity diffusion region (p⁺) provided in the vicinity of the upper surface of the semiconductor substrate W1. The N-type well region NW is an N-type impurity diffusion region (n⁺) provided in the vicinity of the upper surface of the semiconductor substrate W1. The P-type well region PW and the N-type well region NW correspond to the sealing portions ES1 and ES2, respectively.

In the wall region WR, the second CMOS layer 200 includes, similarly to the core region CR, insulating layers 70 and 71, conductive layers 72 to 75, a through via 59, and contacts 78 to 80. The semiconductor substrate W2 includes, similarly to the core region CR, an insulating film region INS penetrated by a plurality of through vias 59.

With the above structure, in the wall region WR, the first CMOS chip CCP1 and the second CMOS chip CCP2 are electrically connected to each other via the through via group Gv penetrating the insulating film region INS. A through via group Gv including the plurality of through vias 59 penetrating the insulating film region INS is connected to a wiring group Gi including a plurality of conductive layers 54 (wirings) provided in the wiring layer D2. One of the plurality of conductive layers 54 in the wiring group Gi of the wiring layer D2 is electrically connected to the P-type well region PW provided in the semiconductor substrate W1. Another one of the plurality of conductive layers 54 in the wiring group Gi of the wiring layer D2 is electrically connected to the N-type well region NW provided in the semiconductor substrate W1.

In the wall region WR, the memory layer 300 includes, similarly to the peripheral region PR, insulating layers 33 to 35, conductive layers 21a, 21b, and 26 to 28, a sacrificial member 37, and contacts CC, V1, and V2.

In the wall region WR, the wiring layer 400 includes, similarly to the core region CR, an insulating layer 91, an insulating layer 92, a conductive layer 93, an insulating layer 94, an insulating layer 95, and an insulating layer 96.

A portion of the conductive layer 93 penetrates the conductive layer 21a, the sacrificial member 37, the conductive layer 21b, and the insulating layers 91 and 92. The conductive layer 93 may have a portion in contact with the contact CC. The upper portion of the contact CC is covered with the conductive layer 93 and is electrically connected to the conductive layer 93. Thus, the conductive layer 93 is connected to the P-type well region PW via the contacts CC, V1, V2, 78 to 80, and 56 to 58, the through via 59, and the conductive layers 26 to 28, 72 to 75, and 52 to 54, which correspond to the sealing portion ES1. Further, the conductive layer 93 is connected to the N-type well region NW via the contacts CC, V1, V2, 78 to 80, and 56 to 58, the through via 59, and the conductive layers 26 to 28, 72 to 75, and 52 to 54, which correspond to the sealing portion ES2.

Although not shown, the sets including the contacts CC, V1, V2, 78 to 80, and 56 to 58, the through via 59, and the conductive layers 26 to 28, 72 to 75, and 52 to 54 are provided in an annular shape in a plan view. The insulating film region INS is provided in an annular shape in a plan view. That is, in the wall region WR, each of the sealing portions ES1 and ES2 is provided in a rectangular ring shape to surround the outer periphery of the core region CR and surround the peripheral region PR. The sealing portion ES2 is disposed closer to the outside than the sealing portion ES1. The insulating film region INS is also provided in a rectangular ring shape to surround the outer periphery of the core region CR, and surrounds the peripheral region PR.

The sealing portions ES1 and ES2 described above are structures capable of releasing positive and negative charges generated inside and outside the wall region WR to the semiconductor substrate W1. Furthermore, each of the sealing portions ES1 and ES2 can reduce the permeation of moisture and the like from the outside of the wall region WR into the core region CR. Each of the sealing portions ES1 and ES2 can reduce stress generated in an interlayer insulating film (for example, tetraethoxysilane (TEOS)) of the semiconductor device 1. Each of the sealing portions ES1 and ES2 can also be used as a crack stopper.

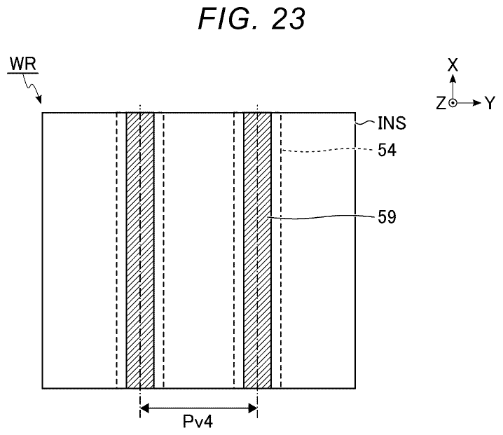

FIG. 23 is a plan view diagram showing an example of a planar layout of the through vias 59 in the wall region WR of the semiconductor device 1. FIG. 23 shows an example in which two through vias 59 penetrate the insulating film region INS, and the conductive layers 54 connected to the through vias 59 are indicated by dotted lines. As shown in FIG. 23, the plurality of through vias 59 are disposed spaced apart from one another. As described above, the through vias 59 are provided in an annular shape in a plan view, and therefore the plurality of through vias 59 are disposed spaced apart from each other in the X direction or the Y direction. In FIG. 23, the plurality of through vias 59 are spaced apart from one another in the Y direction. The through via 59 has, for example, a line-shaped cross-sectional shape in the XY plane. That is, the cross-sectional shape of each of the plurality of through vias 59 penetrating the insulating film region INS formed in the wall region WR is different from the cross-sectional shape of each of the plurality of through vias 59 penetrating the insulating film region INS formed in the memory region MA. In the following, the pitch between two adjacent through vias 59 will be referred to as “pitch Pv4”.

In the wall region WR, the insulating film region INS formed on the semiconductor substrate W2 is formed in, for example, a region where a sealing portion is disposed. In this region, the pitch between two adjacent through vias 59 is set to a distance that allows positive charges generated inside and outside the wall region WR to be released to the N-type well region NW of the semiconductor substrate W1, and allows negative charges generated inside and outside the wall region WR to be released to the P-type well region PW of the semiconductor substrate W1. Therefore, the pitch Pv4 is larger than the pitch Pv1. That is, the through via group Gv penetrating the insulating film region INS formed in the wall region WR is disposed at a pitch different from the through via group Gv penetrating the insulating film region INS formed in the memory region MA. Furthermore, the pitch Pv4 may be equal to the pitch Pv2, may be smaller than the pitch Pv2, or may be larger than the pitch Pv2.

In the above description, the HV transistors are disposed in the first CMOS layer 100 and the LV transistors are disposed in the second CMOS layer 200, but the present disclosure is not limited to this. The arrangement of transistors in the first CMOS layer 100 and the second CMOS layer 200 may be changed as appropriate depending on the design of the semiconductor device 1.

### <1-4> Method for Manufacturing Semiconductor Device

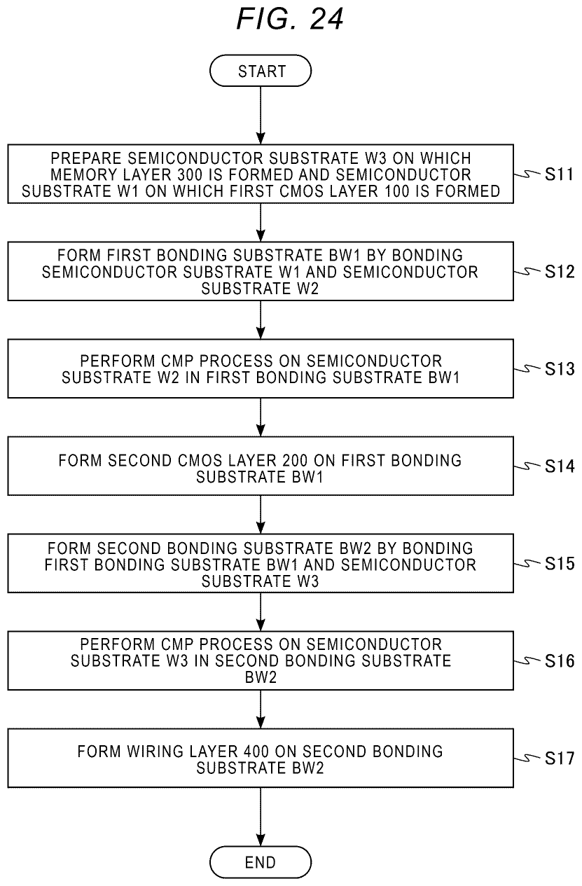

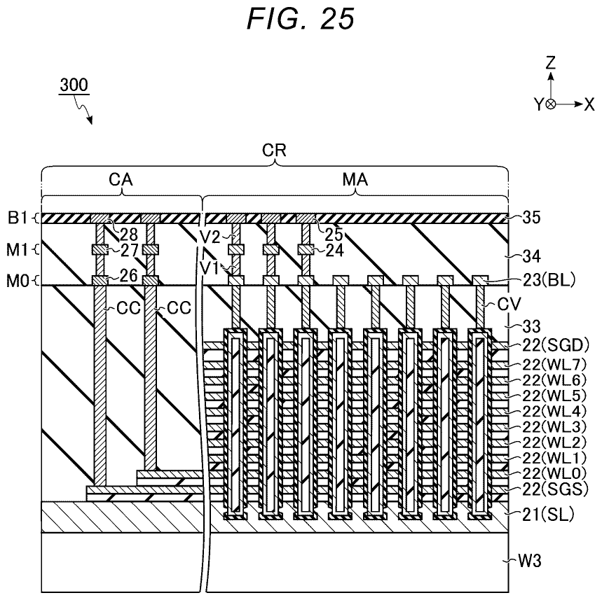

FIG. 24 is a flowchart showing an example of a method for manufacturing the semiconductor device 1 according to the embodiment. Each of FIGS. 25 to 43 is a cross-sectional view diagram showing an example of a cross-sectional structure of the semiconductor device 1 according to the embodiment during the manufacture. The method for manufacturing the semiconductor device 1 according to the embodiment will be described below with reference to FIG. 24.

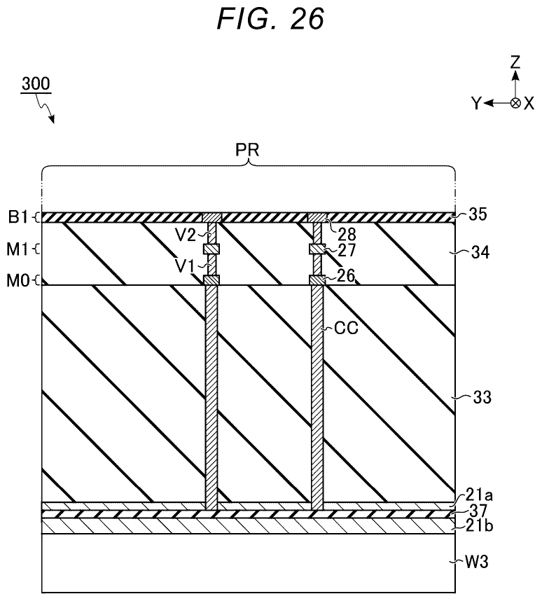

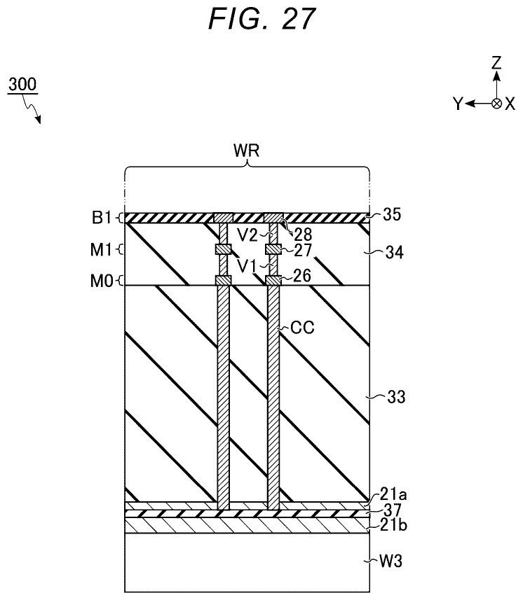

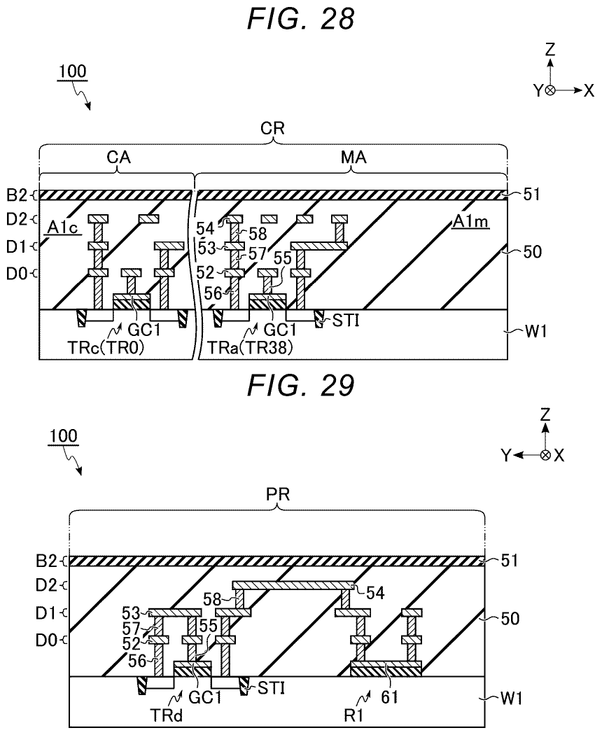

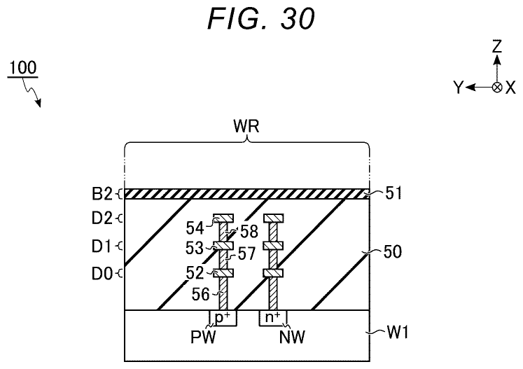

First, a semiconductor substrate W3 on which the memory layer 300 is formed and a semiconductor substrate W1 on which the first CMOS layer 100 is formed are prepared (S11). In the memory layer 300 on the prepared semiconductor substrate W3, as shown in FIGS. 25 to 27, the insulating layer 35 and the bonding pads BP (the conductive layers 25 and 28) provided on the bonding layer B1 are exposed. FIG. 25 is a cross-sectional view diagram showing an example of a cross-sectional structure in the core region CR. FIG. 26 is a cross-sectional view diagram showing an example of a cross-sectional structure in the peripheral region PR. FIG. 27 is a cross-sectional view diagram showing an example of a cross-sectional structure in the wall region WR. In the first CMOS layer 100 on the prepared semiconductor substrate W1, as shown in FIGS. 28 to 30, the insulating layer 51 provided on the bonding layer B2 is exposed. That is, a first CMOS chip CCP1 having a transistor (CMOS circuit) and an insulating layer 51 located above the transistor is formed. FIG. 28 is a cross-sectional view diagram showing an example of a cross-sectional structure in the core region CR. FIG. 29 is a cross-sectional view diagram showing an example of a cross-sectional structure in the peripheral region PR. FIG. 30 is a cross-sectional view diagram showing an example of a cross-sectional structure in the wall region WR. At the time of S11, a structure corresponding to the through via 59 is not formed in the semiconductor substrate W1 and the first CMOS layer 100.

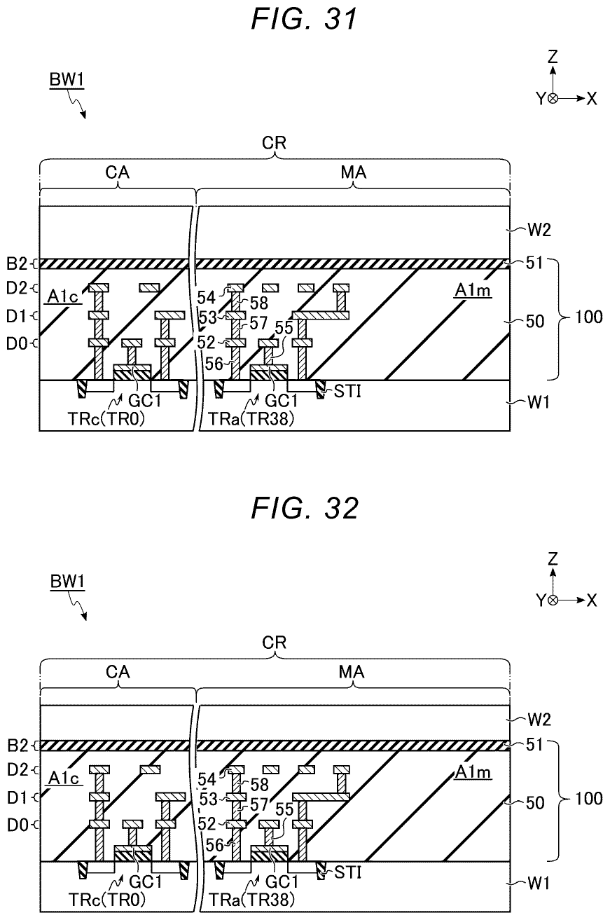

Next, a first bonding substrate BW1 is formed by boding the semiconductor substrate W1 and a semiconductor substrate W2 (S12). Specifically, before the process of S12, a silicon oxide film (insulating film) is formed on the bonded surface of the semiconductor substrate W2. That is, a second CMOS chip CCP2 having the semiconductor substrate W2 and the silicon oxide film provided on the semiconductor substrate W2 is formed. Then, the silicon oxide film of the second CMOS chip CCP2 is bonded onto the insulating layer 51 of the first CMOS chip CCP1. By the bonding process of the semiconductor substrate W1 and the semiconductor substrate W2, the insulating layer 51 (silicon oxide film) of the first CMOS chip CCP1 and the silicon oxide film of the second CMOS chip CCP2 are brought into contact with each other and bonded to each other. Thus, the first bonding substrate BW1 having a structure in which the semiconductor substrate W2 is provided on the insulating layer 51 is formed, as shown in FIG. 31. FIG. 31 is a cross-sectional view diagram showing an example of a cross-sectional structure in the core region CR.

Next, a chemical mechanical polishing (CMP) process is performed on the semiconductor substrate W2 in the first bonding substrate BW1 (S13). By the process of S13, the semiconductor substrate W2 of the first bonding substrate BW1 is polished (thinned) as shown in FIG. 32. FIG. 32 is a cross-sectional view diagram showing an example of a cross-sectional structure in the core region CR. The thickness of the polished and thinned semiconductor substrate W2 corresponds to the thickness of the semiconductor substrate W2 shown in FIG. 13. The thickness of the semiconductor substrate W2 after the process in S13 is, for example, about 0.5 μm to 2.0 μm.

Next, the second CMOS layer 200 is formed on the first bonding substrate BW1 (S14). Specifically, the following process is executed.

First, an insulating film region STI is provided in the vicinity of the upper surface of the semiconductor substrate W2 to surround the active area AA of the transistor. The insulating film region STI contacts the upper surface of the semiconductor substrate W2. A gate insulating film is provided on the semiconductor substrate W2. A conductive layer GC2 is provided on the gate insulating film. As shown in FIG. 33, the conductive layer GC2 is processed. Using the conductive layer GC2 as a mask, an impurity diffusion region is provided the semiconductor substrate W2. Thus, a transistor (CMOS circuit) is formed on the semiconductor substrate W2. FIG. 33 is a cross-sectional view diagram showing an example of a cross-sectional structure in the core region CR.

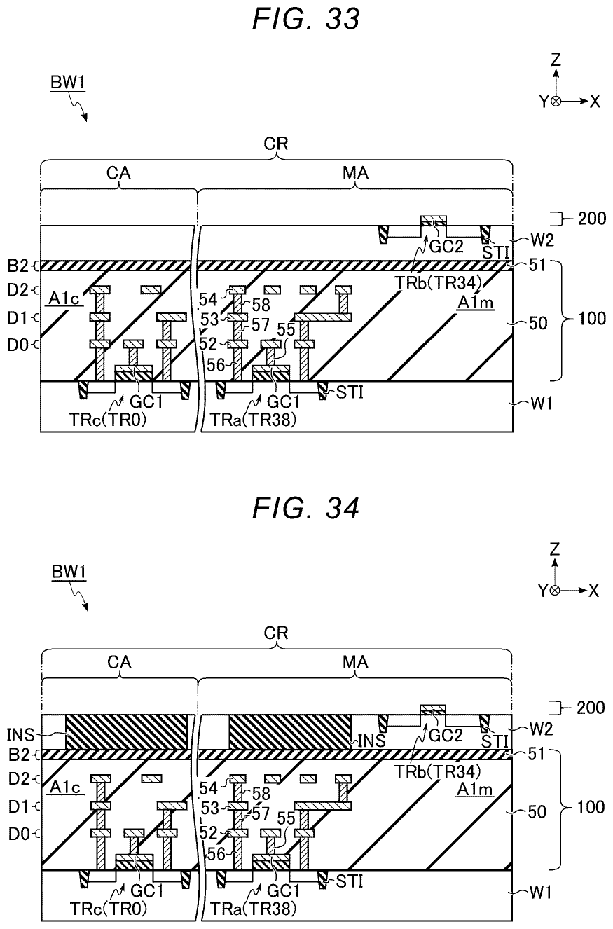

Next, a first hole penetrating the semiconductor substrate W2 is formed to overlap the conductive layer 54 (wiring) in the Z direction. In the memory region MA, the contact region CA, and the wall region WR, first holes penetrating the semiconductor substrate W2 are formed to overlap a plurality of the conductive layers 54 in the Z direction. In the peripheral region PR, a first hole penetrating the semiconductor substrate W2 is formed to overlap one conductive layer 54. Then, an insulator is filled into the first hole. Thus, as shown in FIG. 34, an insulating film region INS penetrating the semiconductor substrate W2 is formed. FIG. 34 is a cross-sectional view diagram showing an example of a cross-sectional structure in the core region CR. The insulating film region INS penetrating the semiconductor substrate W2 is formed in each of the memory region MA, the contact region CA, the peripheral region PR, and the wall region WR. Furthermore, the insulating film region INS may be formed simultaneously with the insulating film region STI. In this case, the number of steps and the cost can be reduced.

Next, an activation annealing process is performed on the semiconductor substrate W2 in the first bonding substrate BW1. Thus, a source and a drain are formed in the impurity diffusion region of the semiconductor substrate W2. The activation annealing process is performed under conditions of, for example, 1000° C. to 1100° C. and 0 to 30 seconds. For example, spike annealing is used to minimize the diffusion of impurities. Spike annealing is performed by simply increasing and decreasing the temperature, with the time at the maximum temperature being set to 0 seconds. As described above, a conductive material having a relatively high melting point is used as the material of the conductive layers 52 to 54 provided in the first CMOS layer 100, and an HV transistor is provided on the semiconductor substrate W1. This makes it possible to reduce deterioration of the characteristics of the transistors provided on the semiconductor substrate W1. Furthermore, the activation annealing process may be performed on both of the semiconductor substrates W1 and W2.

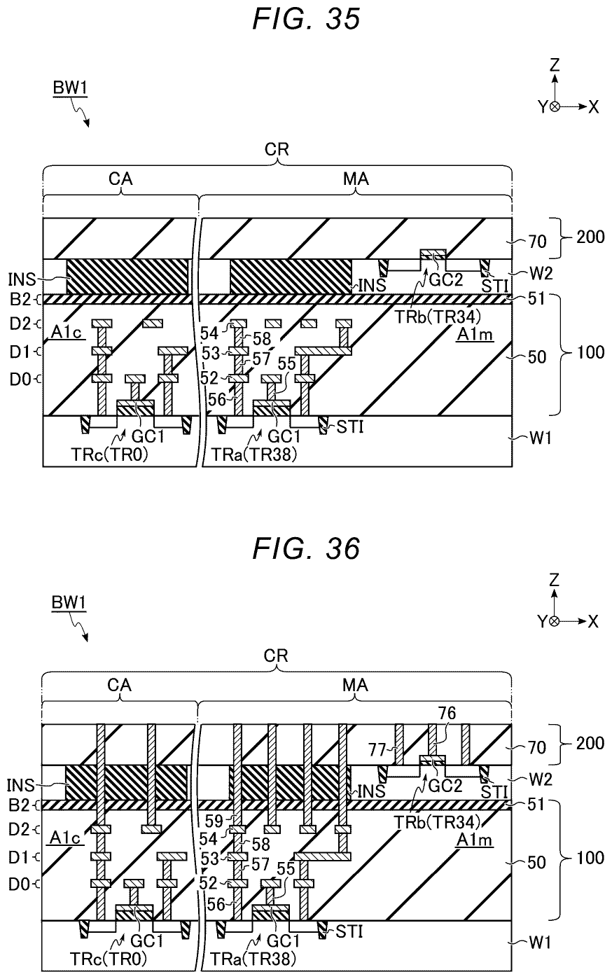

Next, as shown in FIG. 35, an insulating layer 70 is formed. FIG. 35 is a cross-sectional view diagram showing an example of a cross-sectional structure in the core region CR.

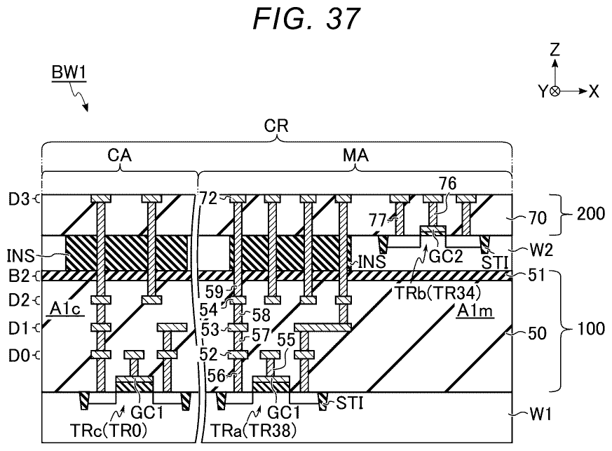

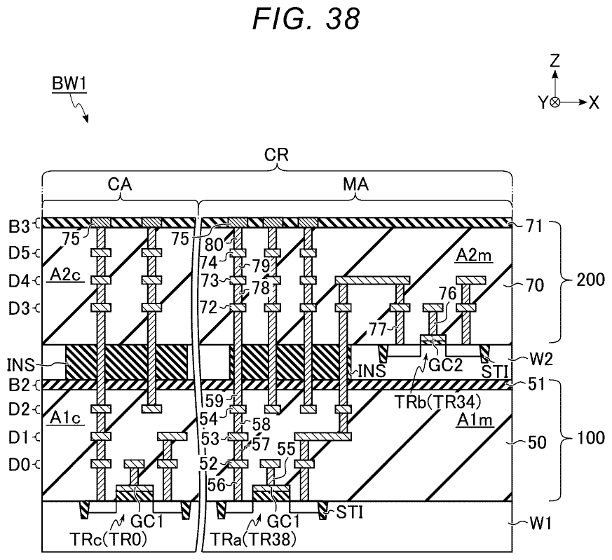

Next, as shown in FIG. 36, contacts 76 and 77 and through vias 59 are formed. FIG. 36 is a cross-sectional view diagram showing an example of a cross-sectional structure in the core region CR. After the contacts 76 and 77 and the through vias 59 are formed, a wiring layer D3 (conductive layer 72) is formed as shown in FIG. 37. FIG. 37 is a cross-sectional view diagram showing an example of a cross-sectional structure in the core region CR. For example, the contacts 76 and 77, the through via 59, and the wiring layer D3 are formed by single damascene.

First, holes respectively corresponding to the contacts 76 and 77, and a plurality of second holes penetrating the insulating film region INS formed in the semiconductor substrate W2 are simultaneously formed, for example, by etching. Thus, holes that reach the conductive layer GC2 of the transistor (CMOS circuit) are formed. Holes that reach the source or drain of the transistor (CMOS circuit) are formed. A plurality of second holes penetrating the insulating film region INS are formed in each of the memory region MA, the contact region CA, the peripheral region PR, and the wall region WR. At this time, for example, a plurality of second holes penetrating the insulating film region INS of the memory region MA and a plurality of second holes penetrating the insulating film region INS of the contact region CA are formed at different pitches.

Thereafter, the holes corresponding to the contacts 76 and 77 and the second hole penetrating the insulating film region INS are filled with a conductor, thereby forming the contacts 76 and 77 and the through via 59. Thus, for example, the contact 76 that is connected to the conductive layer GC2 of a transistor (CMOS circuit) is formed. The contact 77 that is connected to the source or drain of the transistor (CMOS circuit) is formed. Further, for example, a through via group Gv including a plurality of through vias 59 penetrating the insulating film region INS of the memory region MA and a through via group Gv including a plurality of through vias 59 penetrating the insulating film region INS of the contact region CA are formed at different pitches.

Next, a groove corresponding to the wiring layer D3 is formed by, for example, etching. Thereafter, a conductor is filled into the grooves corresponding to the wiring layer D3, thereby forming the wiring layer D3. Thus, for example, a conductive layer 72 is formed on the contact 77 that is connected to the source or drain of the transistor (CMOS circuit). Further, for example, in each of the memory region MA, the contact region CA, the peripheral region PR, and the wall region WR, a wiring group Gi is formed on the through via group Gv penetrating the insulating film region INS and in the same layer as the conductive layer 72.

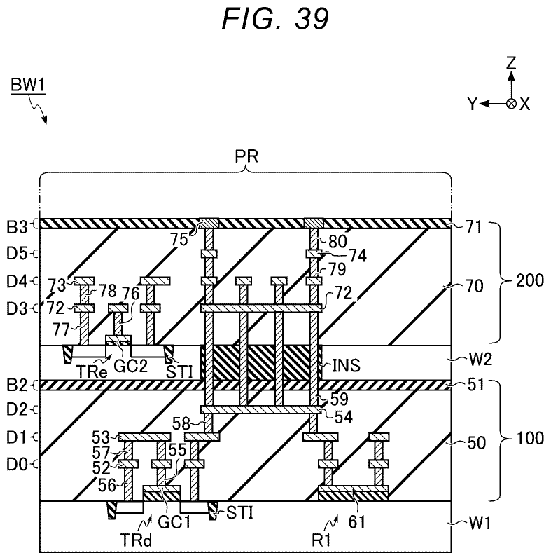

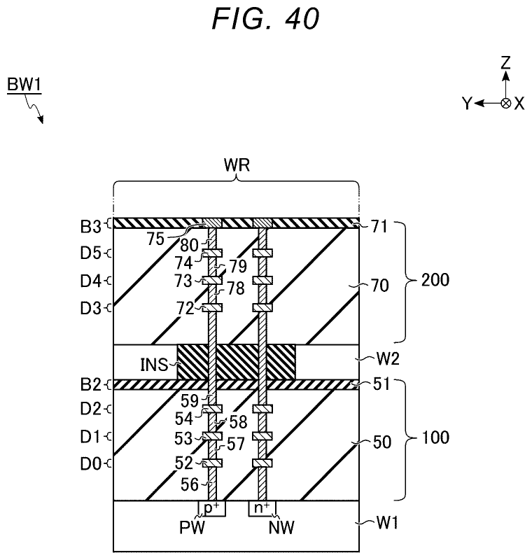

Next, as shown in FIGS. 38 to 40, a structure including wiring layers D4 and D5 and a bonding layer B3 is formed, and the process of S14 is completed. FIG. 38 is a cross-sectional view diagram showing an example of a cross-sectional structure in the core region CR. FIG. 39 is a cross-sectional view diagram showing an example of a cross-sectional structure in the peripheral region PR. FIG. 40 is a cross-sectional view diagram showing an example of a cross-sectional structure in the wall region WR.

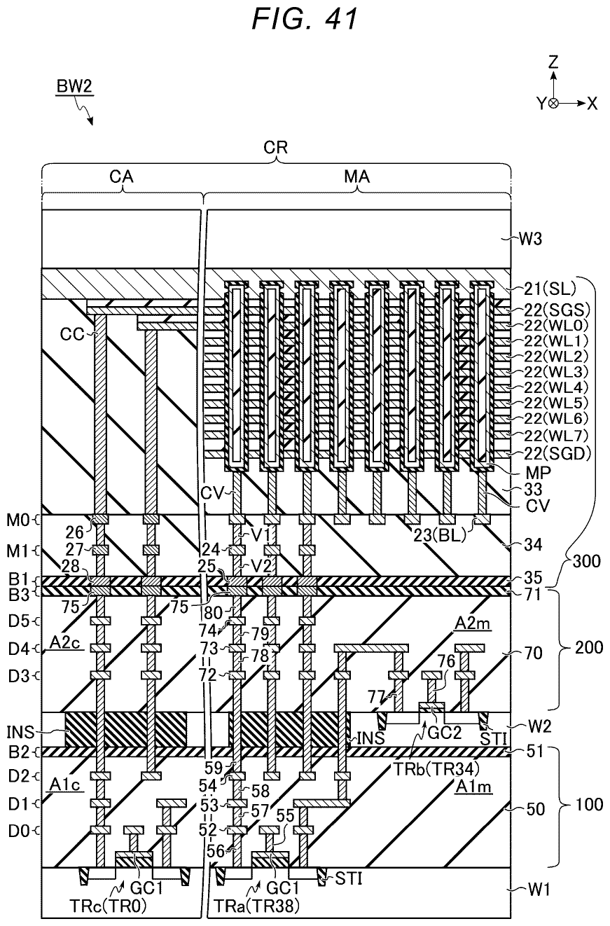

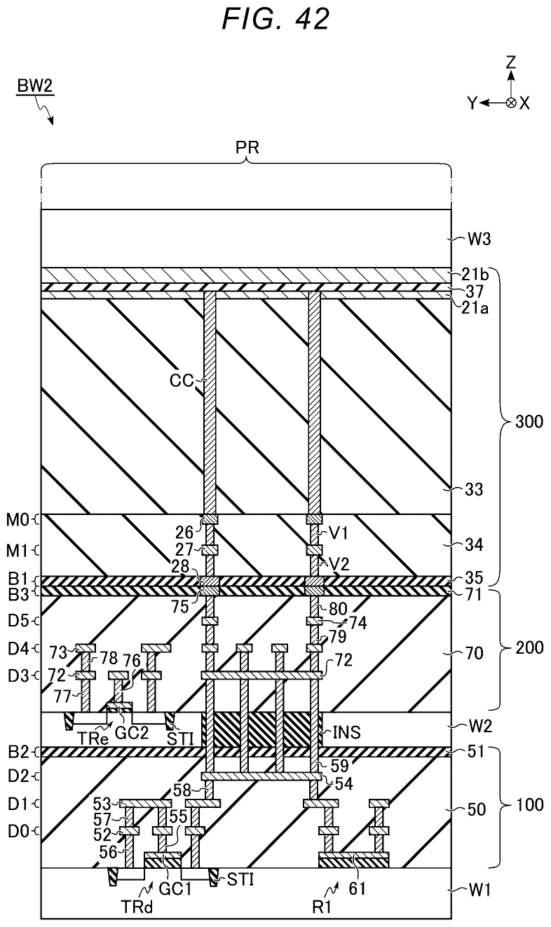

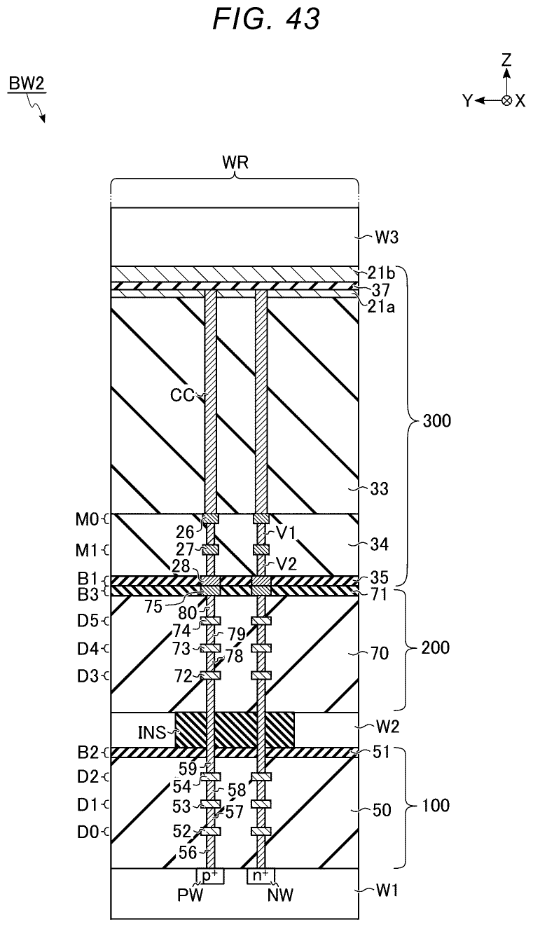

Next, a second bonding substrate BW2 is formed by boding the first bonding substrate BW1 and the semiconductor substrate W3 (S15). Specifically, the insulating layer 71 of the second CMOS layer 200 and the insulating layer 35 of the memory layer 300 are brought into contact with each other and bonded to each other by the bonding process of the first bonding substrate BW1 and the semiconductor substrate W3. Further, a set including opposing bonding pads BP are in contact with each other and coupled between the second CMOS layer 200 and the memory layer 300. Thus, the second bonding substrate BW2 is formed as shown in FIGS. 41 to 43. FIG. 41 is a cross-sectional view diagram showing an example of a cross-sectional structure in the core region CR. FIG. 42 is a cross-sectional view diagram showing an example of a cross-sectional structure in the peripheral region PR. FIG. 43 is a cross-sectional view diagram showing an example of a cross-sectional structure in the wall region WR.

Next, a CMP process is performed on the semiconductor substrate W3 in the second bonding substrate BW2 (S16). By the process of S16, the semiconductor substrate W3 of the second bonding substrate BW2 is removed. Furthermore, the semiconductor substrate W3 may be left without being removed but only thinned.

Next, the wiring layer 400 is formed on the second bonding substrate BW2 (S17). On the conductive layer 21, an insulating layer 91, an insulating layer 92, a conductive layer 93, an insulating layer 94, an insulating layer 95, and an insulating layer 96 are formed in this order. When the process of S17 is completed, the semiconductor device 1 is completed.

### <1-5> Advantages of Embodiment

According to the semiconductor device 1 according to the embodiment, the chip area of the semiconductor device 1 can be reduced. The advantages of the embodiment will be described in detail below.

There is a semiconductor device having an array chip including a memory cell array 10, a first CMOS chip in which a CMOS circuit for controlling the memory cell array 10 is disposed on a semiconductor substrate, and a second CMOS chip in which a CMOS circuit for controlling the memory cell array 10 is disposed on a semiconductor substrate.

In such a semiconductor device, for example, the first CMOS chip and the second CMOS chip can be electrically connected to each other by using a through via covered with an insulating film region. Further, for example, CMOS circuits may be disposed in different areas for different applications. The number of CMOS circuits disposed in each area may vary depending on the application. That is, the number of CMOS circuits disposed may differ from area to area. Therefore, the number of through vias connecting the first CMOS chip and the second CMOS chip also differs depending on the application, and may differ from area to area.

A memory cell array in which memory cells are stacked three-dimensionally can increase the storage capacity by increasing the number of stacked word lines WL. However, when the number of stacked word lines WL is increased to increase capacity, the number of through vias connected to the word lines WL and connecting the first CMOS chip and the second CMOS chip may also increase. When the number of through vias increases, the area of the insulating film region surrounding the through vias increases in proportion to the increased number, so that the chip area of the semiconductor device 1 may increase.

Additionally, supplied to CMOS circuits may vary depending on the application. Therefore, when the distance between two adjacent through vias is made the same in every area regardless of the application, for example, dielectric breakdown may occur between the two adjacent through vias depending on the voltage supplied to the CMOS circuit.

In contrast, in the semiconductor device 1 according to the present embodiment, the semiconductor substrate W2 includes an insulating film region INS penetrating the semiconductor substrate W2 in each of the core region CR, the peripheral region PR, and the wall region WR. Each insulating film region INS includes a plurality of through vias 59 that electrically connect the first CMOS chip CCP1 and the second CMOS chip CCP2. In other words, the plurality of through vias 59 electrically connecting the first CMOS chip CCP1 and the second CMOS chip CCP2 penetrate one insulating film region INS. In each of the core region CR, the peripheral region PR, and the wall region WR, the plurality of through vias 59 are disposed in the insulating film region INS at different pitches depending on the application. This allows the pitch arrangement to be optimized within the insulating film region INS. Therefore, the area of the insulating film region INS can be reduced as compared with the case where the plurality of through vias 59 are disposed at the same pitch within the insulating film region INS regardless of the application. Therefore, the chip area of the semiconductor device 1 can be reduced.

There is also a semiconductor device in which a first CMOS chip and a second CMOS chip are bonded to each other via bonding pads provided on the first CMOS chip and bonding pads provided on the second CMOS chip.

In such a semiconductor device, the arrangement of the through vias connecting the first CMOS chip and the second CMOS chip is limited by the distance between two adjacent bonding pads. Furthermore, when bonding pads are bonded to each other, poor bonding may occur.

In contrast, in the present embodiment, an insulating film (silicon oxide film) of a semiconductor substrate W2 having the insulating film is bonded onto an insulating layer 51 of a semiconductor substrate W1 having a CMOS circuit and the insulating layer 51 located above the CMOS circuit. That is, no bonding pads are used. This allows the through vias 59 that connect the first CMOS chip CCP1 and the second CMOS chip CCP2 to be disposed without being limited by the distance between the bonding pads. Therefore, the chip area of the semiconductor device 1 can be reduced. Furthermore, since no bonding pads are used, poor bonding between the bonding pads does not occur. Furthermore, the process can be simplified as compared with the case where the first CMOS chip and the second CMOS chip are bonded to each other via a bonding pad.

### <1-6> First Modification

A semiconductor device 1A according to a first modification of the embodiment will be described. In the semiconductor device 1A according to this modification, the structure in the vicinity of the upper surface of the through via 59 is different from the structure of the embodiment. The following description will focus on the differences from the embodiment.

### <1-6-1> Cross-Sectional Structure of Semiconductor Device

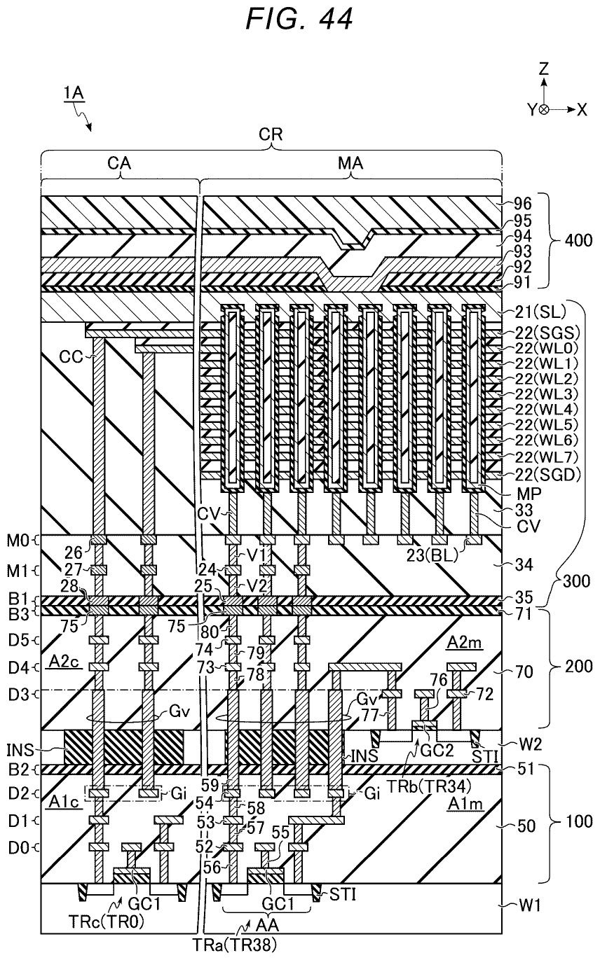

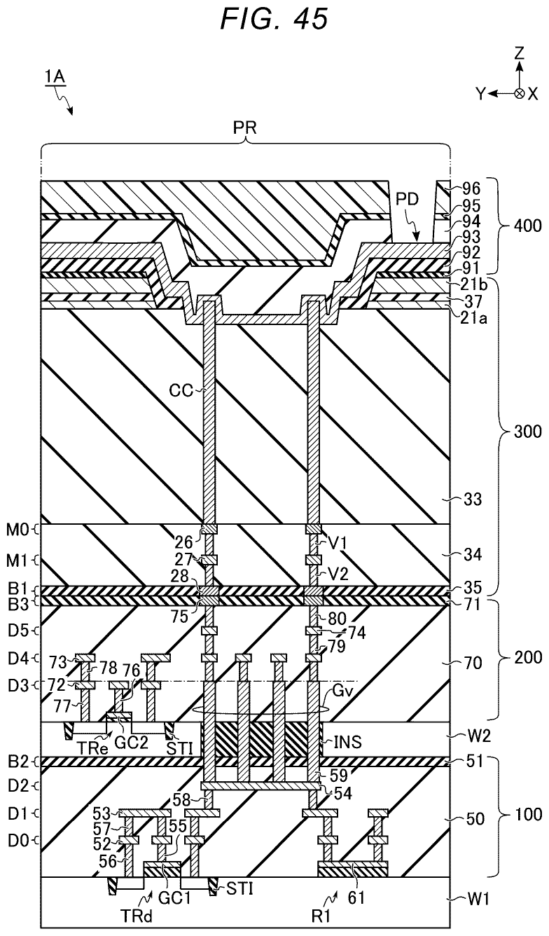

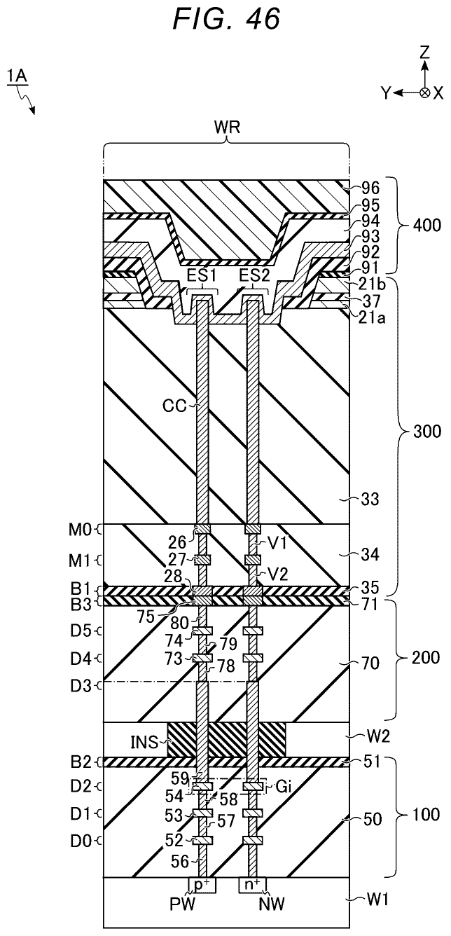

FIG. 44 is a cross-sectional view diagram showing an example of a cross-sectional structure of a core region CR of the semiconductor device 1A according to the first modification. FIG. 45 is a cross-sectional view diagram showing an example of a cross-sectional structure of a peripheral region PR of the semiconductor device 1A according to the first modification. FIG. 46 is a cross-sectional view diagram showing an example of a cross-sectional structure of a wall region WR of the semiconductor device 1A according to the first modification. As shown in FIGS. 44 to 46, in the semiconductor device 1A, the wiring group Gi provided above the through via group Gv penetrating the insulating film region INS and in the same layer as the conductive layer 72 from the semiconductor device 1 according to the embodiment is eliminated. The position of the upper surface of each of the plurality of through vias 59 penetrating the insulating film region INS is the same as the position of the upper surface of the conductive layer 72 electrically connected to one of the source or drain of the transistor TRb. Each of the plurality of through vias 59 penetrating the insulating film region INS is connected to a contact 78.

Other structures of the semiconductor device 1A are similar to those of the semiconductor device 1 according to the embodiment.

### <1-6-2> Method for Manufacturing Semiconductor Device

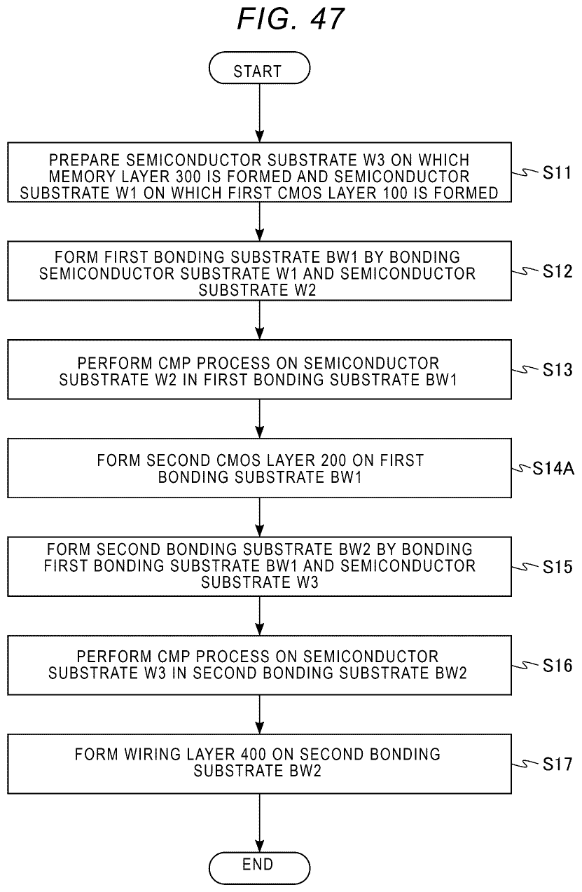

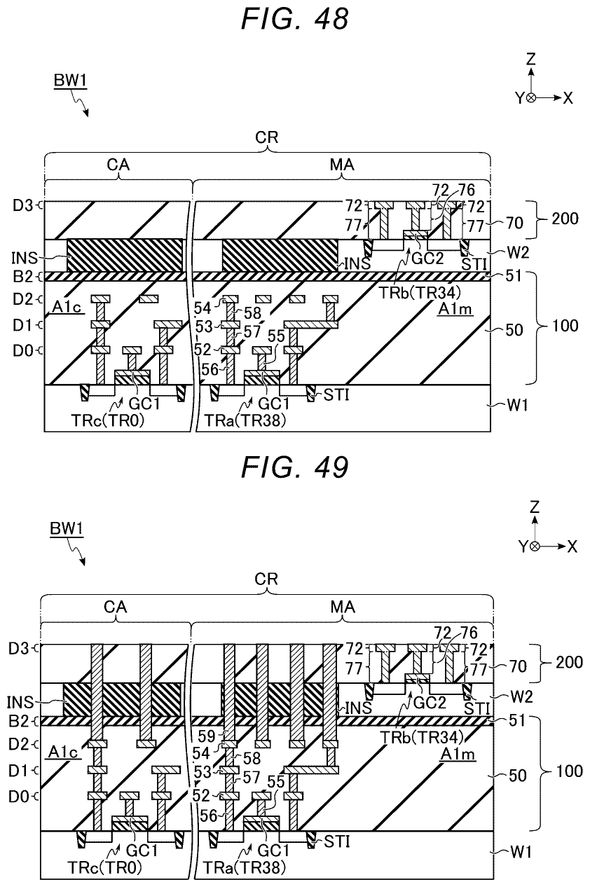

FIG. 47 is a flowchart showing an example of a method for manufacturing the semiconductor device 1A according to the first modification. In the flowchart of the method for manufacturing the semiconductor device 1A shown in FIG. 47, S14 in the flowchart of FIG. 24 shown in the embodiment is replaced with S14A. The steps other than S14A are the same as those in the flowchart of FIG. 24 shown in the embodiment. Each of FIGS. 48 and 49 is a cross-sectional view diagram showing an example of a cross-sectional structure of the semiconductor device 1A according to a first modification during the manufacture. The method for manufacturing the semiconductor device 1A will be described below with reference to FIG. 47.

In S14A, the second CMOS layer 200 is formed on the first bonding substrate BW1. Specifically, the following process is executed.

The steps from the formation of the transistors (CMOS circuits) to the formation of the insulating layer 70 are the same as those in the embodiment.

Next, as shown in FIG. 48, contacts 76 and 77 and a wiring layer D3 (conductive layer 72) are formed. FIG. 48 is a cross-sectional view diagram showing an example of a cross-sectional structure in the core region CR. For example, the contacts 76 and 77 and the wiring layer D3 are integrally formed by dual damascene.

First, holes corresponding to the contacts 76 and 77, respectively, and a groove corresponding to the wiring layer D3 are formed, for example, by etching. Thus, holes that reach the conductive layer GC2 of the transistor (CMOS circuit) are formed. Holes that reach the source or drain of a transistor (CMOS circuit) are formed. A groove corresponding to the wiring layer D3 is formed.

Thereafter, conductors are filled into the holes corresponding to the contacts 76 and 77, respectively, and into the groove corresponding to the wiring layer D3, thereby integrally forming the contacts 76 and 77, and the wiring layer D3. Thus, for example, the contact 76 that is connected to the conductive layer GC2 of a transistor (CMOS circuit) is formed. The contact 77 that is connected to the source or drain of the transistor (CMOS circuit) is formed. Thus, for example, a conductive layer 72 is formed on the contact 76 connected to the conductive layer GC2 of the transistor (CMOS circuit). The conductive layer 72 is formed on the contact 77 that is connected to the source or drain of the transistor (CMOS circuit).

Next, as shown in FIG. 49, through vias 59 are formed. FIG. 49 is a cross-sectional view diagram showing an example of a cross-sectional structure in the core region CR.

First, a plurality of second holes penetrating the insulating film region INS formed in the semiconductor substrate W2 are formed by, for example, etching. Thus, a plurality of second holes penetrating the insulating film region INS are formed in each of the memory region MA, the contact region CA, the peripheral region PR, and the wall region WR. At this time, for example, a plurality of second holes penetrating the insulating film region INS of the memory region MA and a plurality of second holes penetrating the insulating film region INS of the contact region CA are formed at different pitches.

Thereafter, a conductor is filled into the second hole penetrating the insulating film region INS, thereby forming a through via 59. Thus, for example, a through via group Gv including a plurality of through vias 59 penetrating the insulating film region INS of the memory region MA and a through via group Gv including a plurality of through vias 59 penetrating the insulating film region INS of the contact region CA are formed at different pitches.

The subsequent steps of forming the structure of the wiring layers D4 and D5 and the bonding layer B3 are the same as those in the embodiment.

### <1-6-3> Advantages of First Modification

According to this modification, the same advantages as those of the embodiment are achieved.

Furthermore, when forming a conductive layer 72 on the through via 59, for example, a lower resist film may be sucked into the through via 59 during photolithography of the conductive layer 72, which may cause the photolithography pattern to collapse. To avoid this, it is necessary to repeat the application and etch-back of the lower resist film, which increases the number of steps.

In contrast, in this modification, the conductive layer 72 is not provided on the through via 59. Therefore, according to this modification, the number of steps can be reduced compared to the case where the conductive layer 72 is provided on the through via 59.

### <1-7> Second Modification

A semiconductor device 1B according to a second modification of the embodiment will be described. In the semiconductor device 1B according to this modification, the structure of the peripheral region PR is different from that of the embodiment. The following description will focus on the differences from the embodiment.

### <1-7-1> Cross-Sectional Structure of Semiconductor Device

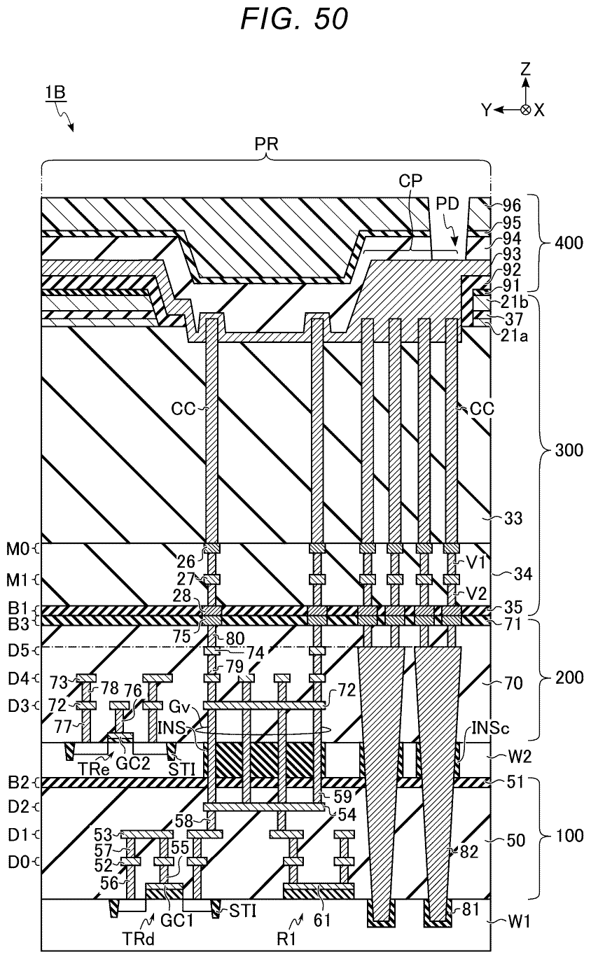

FIG. 50 is a cross-sectional view diagram showing an example of a cross-sectional structure of a peripheral region PR of the semiconductor device 1B according to the second modification. As shown in FIG. 50, in the semiconductor device 1B, a chip connection portion CP is added to the peripheral region PR of the semiconductor device 1 according to the embodiment.

For example, the chip connection portion CP is disposed spaced apart from the insulating film region INS in the Y direction. The chip connection portion CP includes an insulating layer 81, a through via 82, an insulating film region INSc, conductive layers 74 and 75, contacts 79 and 80, conductive layers 26 to 28, contacts CC, V1, and V2, and a conductive layer 93.

In the chip connection portion CP, the insulating layer 81 is provided in the vicinity of the upper surface of the semiconductor substrate W1. The through via 82 is provided on the insulating layer 81. The through via 82 is in the first CMOS chip CCP1 and the second CMOS chip CCP2. The side surface and bottom surface of the lower end of the through via 82 are covered with the insulating layer 81. The upper surface of the through via 82 is located higher than the respective upper surfaces of the plurality of through vias 59 in the through via group Gv. The lower surface of the through via 82 is located lower than the lower surfaces of the plurality of through vias 59 in the through via group Gv. In the XY plane, the cross-sectional area of the upper surface of the through via 82 is larger than the cross-sectional area of each of the plurality of through vias 59 in the through via group Gv. The semiconductor substrate W2 is provided with the insulating film region INSc penetrating the semiconductor substrate W2. That is, the semiconductor substrate W2 includes the insulating film region INSc penetrating the semiconductor substrate W2. The through via 82 penetrates the insulating layers 50 and 51 and the insulating film region INSc. The through via 82 contacts the semiconductor substrate W1 via the insulating layer 81. The through via 82 has, for example, a taper shape in which the cross-sectional area decreases from the upper surface to the lower surface. In the example of FIG. 50, two through vias 82 are provided. Two contacts 79 are provided on the through via 82. The conductive layer 75 is provided on each of the two contacts 79 connected to one through via 82. That is, in the XY plane, the cross-sectional area of the upper surface of the through via 82 is larger than the cross-sectional area of the bonding pad BP (the conductive layer 75). The through via 82 is connected to the conductive layer 93 via the contact 79, the conductive layer 74, the contact 80, the conductive layer 75, the conductive layer 28, the contact V2, the conductive layer 27, the contact V1, the conductive layer 26, and the contact CC. Thus, the pad PD is connected to the through via 82 via the contacts CC, V1, V2, 79, and 80 and the conductive layers 26 to 28, 74, and 75. Furthermore, the lower end of the through via 82 may not reach the semiconductor substrate W1, and the lower end of the through via 82 may be in contact with the wiring layer D0 (conductive layer 52).

With the above structure, in the peripheral region PR, wirings penetrating the insulating film region INSc that are in the first CMOS chip CCP1 and the second CMOS chip CCP2 and are provided on the semiconductor substrate W2, that is, the through vias 82, are formed. The through vias 82 are used, for example, for electrical connection between the semiconductor device 1B and another semiconductor device 1B. In contrast, the through vias 59 are used for electrical connection between the first CMOS chip CCP1 and the second CMOS chip CCP2, for example.

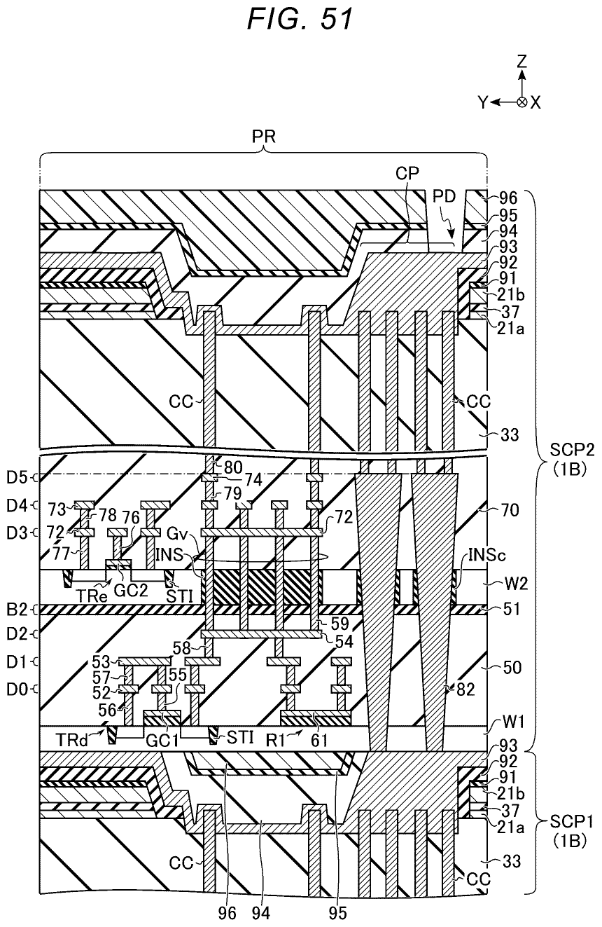

FIG. 51 is a cross-sectional view diagram showing an example of a cross-sectional structure when a plurality of semiconductor devices 1B are stacked. In the example of FIG. 51, a semiconductor device 1B (hereinafter referred to as a “semiconductor chip SCP2”) is stacked on a semiconductor device 1B (hereinafter referred to as a “semiconductor chip SCP1”). As shown in FIG. 51, in the semiconductor chip SCP1, the conductive layer 93 is exposed, a part of the insulating layer 94 is exposed, and a part of the insulating layer 95 is exposed. In the semiconductor chip SCP2, the insulating layer 81 is removed. The through vias 82 of the semiconductor chip SCP2 are provided on the conductive layer 93 of the semiconductor chip SCP1. Thus, the semiconductor chip SCP1 and the semiconductor chip SCP2 are electrically connected to each other via the through via 82. The semiconductor device 1B can be stacked in three or more layers in the same manner as in FIG. 51.

### <1-7-2> Advantages of Second Modification

According to this modification, the same advantages as those of the embodiment are achieved. Of course, the first modification can also be applied to this modification.

Moreover, according to this modification, a plurality of semiconductor devices 1B can be stacked, and the pad PD can be electrically connected to each semiconductor device 1B via the through via 82.

### <2> Other

As described above, the semiconductor device (1) according to the embodiment includes a first chip (CCP1) having a first substrate (W1) on which a first transistor (TRa) is formed, and a second chip (CCP2) provided above the first chip and having a second substrate (W2) on which a second transistor (TRb) is formed. The second substrate (W2) includes a first insulating film region (INS) and a second insulating film region (INS), each penetrating the second substrate. The first chip (CCP1) and the second chip (CCP2) are electrically connected to each other via a first through via group (Gv) including at least a first via (59) and a second via (59) each penetrating the first insulating film region (INS), and a second through via group (Gv) including at least a third via (59) and a fourth via (59) each penetrating the second insulating film region (INS). The first through via group (Gv) is disposed at a pitch different from that of the second through via group (Gv).

Furthermore, the embodiment is not limited to the above-described embodiment, and various modifications are possible.

Furthermore, in the flowchart described in the above embodiment, the order of the processes can be changed as much as possible.

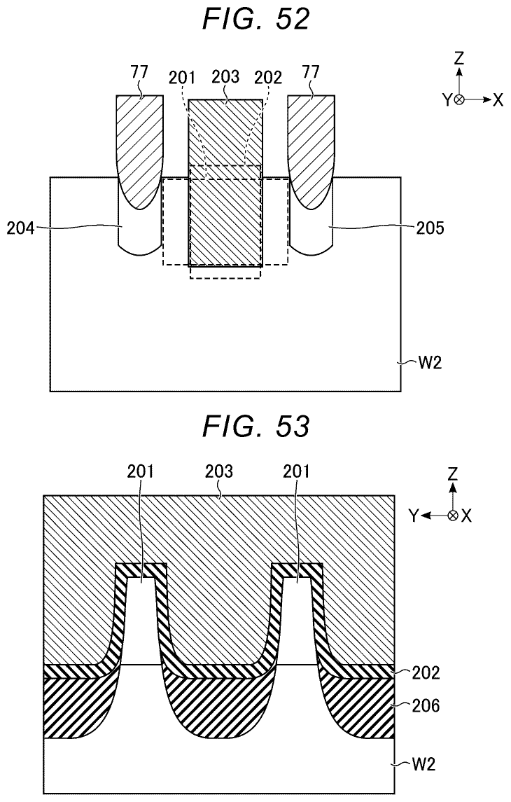

A Fin Field-Effect Transistor (FinFET) may be used as the transistor provided on the semiconductor substrate W2. The FinFET is applicable to the embodiment, the first modification, and the second modification. FIG. 52 is a cross-sectional view in the XZ plane showing an example of the structure of a FinFET. FIG. 53 is a cross-sectional view of the FinFET of FIG. 52 in the YZ plane.

As shown in FIGS. 52 and 53, a semiconductor layer 201 is provided on the semiconductor substrate W2. The semiconductor layer 201 functions as a channel of the FinFET. A gate insulating film 202 is provided on two of the four side surfaces and the upper surface of the semiconductor layer 201. That is, two side surfaces and upper surface (three surfaces) of the semiconductor layer 201 are covered with the gate insulating film 202. A gate electrode 203 is provided on the gate insulating film 202. An electrode 204 is provided to be in contact with one of the two side surfaces of the semiconductor layer 201 that are not covered with the gate insulating film 202. The electrode 204 is either a source electrode or a drain electrode. The electrode 204 is connected to the contact 77. An electrode 205 is provided to be in contact with the other of the two side surfaces of the semiconductor layer 201 that are not covered with the gate insulating film 202. The electrode 205 is the other of the source electrode and the drain electrode. The electrode 205 is connected to a contact 77. An insulating film region 206 (insulating film region STI) is provided below the gate insulating film 202 of the semiconductor substrate W2. By using FinFETs, a leakage current can be reduced.

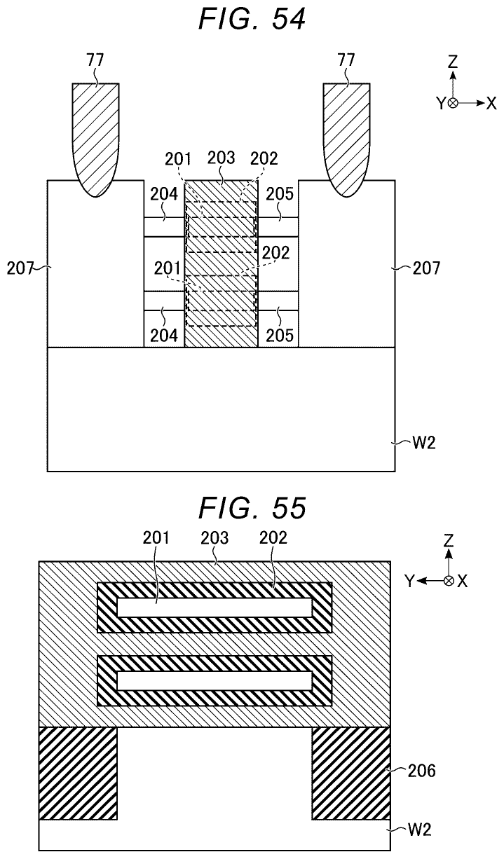

As the transistor provided on the semiconductor substrate W2, a transistor having a Gate All Around (GAA) structure (hereinafter, also referred to as a “GAA transistor”) may be used. The GAA transistor is applicable to the embodiment, the first modification, and the second modification. FIG. 54 is a cross-sectional view in the XZ plane showing an example of the structure of a GAA transistor. FIG. 55 is a cross-sectional view of the GAA transistor of FIG. 54 in the YZ plane. In the example of FIGS. 54 and 55, two semiconductor layers 201 and two gate insulating films 202 are provided.

As shown in FIGS. 54 and 55, a gate electrode 203 is provided on the semiconductor substrate W2. The semiconductor layer 201 has a plate shape extending in the X direction and penetrates the gate electrode 203. The two semiconductor layers 201 are disposed spaced apart from each other in the Z direction. The gate insulating film 202 has a ring shape extending in the X direction and penetrates the gate electrode 203. The two gate insulating films 202 are disposed spaced apart from each other in the Z direction. The gate insulating films 202 are provided on two of the four side surfaces, the upper surface, and the lower surface of the semiconductor layer 201. That is, the two side surfaces, upper surface, and lower surface (four surfaces) of the semiconductor layer 201 are covered with the gate insulating film 202. An electrode 204 is provided to be in contact with one of the two side surfaces of the semiconductor layer 201 that are not covered with the gate insulating film 202. The electrode 204 is either a source electrode or a drain electrode. An electrode 205 is provided to be in contact with the other of the two side surfaces of the semiconductor layer 201 that are not covered with the gate insulating film 202. The electrode 205 is the other of the source electrode and the drain electrode. An insulating film region 206 (insulating film region STI) is provided in the vicinity of the upper surface of the semiconductor substrate W2. An epitaxial layer 207 is provided on the semiconductor substrate W2 to be in contact with the electrode 204. The epitaxial layer 207 is provided on the semiconductor substrate W2 to be in contact with the electrode 205. A contact 77 is provided on the epitaxial layer 207. By using GAA transistors, leakage current can be reduced more than with FinFETs.

When HV transistors are disposed in the first CMOS layer 100 and LV transistors are disposed in the second CMOS layer 200, the impurity concentrations of the semiconductor substrates W1 and W2 can be set according to the types of transistors to be disposed.

For example, the impurity concentration of the semiconductor substrate W1 on which the HV transistor is formed can be set to 1.0×10¹⁴ to 1.0×10¹⁵ [cm⁻³]. The impurity concentration of the semiconductor substrate W2 on which the LV transistor is formed can be set to 5.0×10¹⁴ to 1.0×10¹⁶ [cm⁻³].

When HV transistors are disposed in the first CMOS layer 100 and LV transistors are disposed in the second CMOS layer 200, notches of the semiconductor substrates W1 and W2 may be set according to the types of transistors to be disposed. In this specification, the “notch” is a portion provided in correspondence with the crystal orientation of the semiconductor substrate, and is used as a reference for the direction in which semiconductor manufacturing equipment holds the substrate.

For example, in the semiconductor substrate W1 on which the HV transistor is formed, the Miller indices of the crystal orientation corresponding to the X direction and the Y direction, that is, the Miller indices of the crystal orientation corresponding to the extension direction of the channel of the transistor, may be set to <110>. In this case, the semiconductor substrate W1 has a notch disposed in correspondence with <110>. The semiconductor substrate W1 may be called a “0-degree notch substrate”.

In the semiconductor substrate W2 on which the LV transistor is formed, the Miller indices of the crystal orientation corresponding to the X direction and the Y direction, that is, the Miller indices of the crystal orientation corresponding to the extension direction of the channel of the transistor, may be set to <100>. In this case, the semiconductor substrate W2 has a notch aligned in correspondence with <100>. The semiconductor substrate W2 may be called a “45-degree notch substrate” since it has a configuration in which a notch is disposed at a portion rotated 45 degrees from the semiconductor substrate W1. By using a 45-degree notch substrate as the semiconductor substrate W2, the mobility of carriers can be increased, and the LV transistor can be operated at higher speed.

When HV transistors are disposed in the first CMOS layer 100 and LV transistors are disposed in the second CMOS layer 200, the channel structures of the transistors formed on each of the semiconductor substrates W1 and W2 may be set according to the types of transistors to be disposed.

For example, the channel structure of the HV transistor formed on the semiconductor substrate W1 may be silicon.

For example, the channel structure of the LV transistor formed on the semiconductor substrate W2 may be a structure in which SiGe is epitaxially grown on the semiconductor substrate W2. This makes it possible to improve the characteristics of the LV transistor.

When HV transistors are disposed in the first CMOS layer 100 and LV transistors are disposed in the second CMOS layer 200, the structures of the gate electrodes of the transistors formed on each of the semiconductor substrates W1 and W2 may be set according to the types of transistors to be disposed.

For example, a WSi gate structure, a W polymetal structure, or the like can be applied to the gate electrode of the HV transistor formed on the semiconductor substrate W1.

An HV transistor with a WSi gate structure has a structure in which, for example, polysilicon (Poly-Si), tungsten silicide (WSi), and titanium nitride (TiN) are stacked in this order as a gate electrode on a gate insulating film (oxide film), and silicon nitride (SiN) is formed as a cap layer on the gate electrode.

An HV transistor with a W polymetal structure has a structure in which, for example, polysilicon (Poly-Si), titanium nitride (TiN), tungsten nitride (WN), and tungsten (W) are stacked in this order on a gate insulating film (oxide film) as a gate electrode, and silicon nitride (SiN) is formed on the gate electrode as a cap layer. Such a gate electrode structure may be called a “W polymetal gate”.

For example, a salicide structure can be applied to the gate electrode of the LV transistor formed on the semiconductor substrate W2.

An LV transistor with a salicide structure has a structure in which, for example, polysilicon (Poly-Si) or nickel platinum silicide (NiPtSi) is formed as a gate electrode on a gate insulating film (oxide film). Such a gate electrode structure may be called a “NiPtSi gate”.

The structure of each of the gate electrodes of the semiconductor substrate W1 and the semiconductor substrate W2 is designed in accordance with, for example, reduction in chip area, performance requirements of the input/output circuit 11, and the like.

The semiconductor device 1 is not limited to a NAND flash memory, but may be a dynamic random access memory (DRAM) or a static random access memory (SRAM). In addition, the semiconductor device 1 may be a memory device using a transition metal oxide element having variable resistance characteristics as a memory element (for example, a resistance change memory such as a Resistive Random Access Memory (ReRAM)), a memory device using a phase-change element as a memory element (for example, a phase-change memory such as a Phase Change Random Access Memory (PCRAM)), or a memory device using a ferroelectric element as a memory element (for example, a ferroelectric memory such as Ferroelectric Random Access Memory (FeRAM)). Additionally, other memories and other devices may also be used.

While certain embodiments have been described, these embodiments have been presented by way of example only, and are not intended to limit the scope of the disclosure.

Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first chip including a first substrate on which a first transistor is formed; and
a second chip provided above the first chip and including a second substrate on which a second transistor is formed, wherein
the second substrate includes a first insulating region and a second insulating region each penetrating the second substrate,
the first chip and the second chip are electrically connected to each other via a first group of through vias penetrating the first insulating region and a second group of through vias penetrating the second insulating region, the first group of through vias being arranged at a first pitch, and the second group of through vias being arranged at a second pitch different from the first pitch.

2. The semiconductor device according to claim 1, wherein
the second substrate further includes a third insulating region surrounding an active area of the second transistor, and
the third insulating region has a thickness smaller than a thickness of the second substrate.

3. The semiconductor device according to claim 1, wherein
the first group of through vias is arranged at the first pitch in a first direction and a second direction, and
the second group of through vias is arranged at the second pitch in the first direction and a third direction different from the second direction.

4. The semiconductor device according to claim 1, wherein
the second pitch is greater than the first pitch,
the first group of through vias is arranged in a staggered manner, and
the second group of through vias is arranged in a square.

5. The semiconductor device according to claim 1, wherein
in a cross section parallel to a front surface of the first substrate, a cross-sectional shape of each of through vias in the first group is different from a cross-sectional shape of each of through vias in the second group.

6. The semiconductor device according to claim 5, wherein
the cross-sectional shape of each of the through vias in the first group is a circular shape, and
the cross-sectional shape of each of the through vias in the second group is a linear shape.

7. The semiconductor device according to claim 1, wherein
the first chip further includes a first wiring and a second wiring that are provided in a same layer level and separated from each other,
a first one of through vias in the first group is connected to the first wiring, and
a second one of through vias in the first group is connected to the second wiring.

8. The semiconductor device according to claim 7, wherein
the first chip further includes a third wiring provided in the same layer level as the first and second wirings, and
the second group of through vias is commonly connected to the third wiring.

9. The semiconductor device according to claim 7, wherein
the first chip further includes a fourth wiring and a fifth wiring that are provided in the same layer level as the first and second wirings,
the first substrate includes a first impurity diffusion region and a second impurity diffusion region,
a first one of through vias in the second group is connected between the fourth wiring and the first impurity diffusion region, and
a second one of through vias in the second group is connected between the fifth wiring and the second impurity diffusion region.

10. The semiconductor device according to claim 7, wherein
the second chip further includes a sixth wiring electrically connected to the second transistor, and
upper surfaces of the first group of through vias are flush with an upper surface of the sixth wiring.

11. The semiconductor device according to claim 1, wherein
the second substrate further includes a fourth insulating region penetrating the second substrate, and
the first chip and the second chip are electrically connected to each other also via an extended through via that penetrates the fourth insulating region and has a length greater than the through vias in the first group.

12. The semiconductor device according to claim 11, wherein
an upper surface of the extended through via is located higher than an upper surface of each of the through vias in the first group,
a lower surface of the extended through via is located lower than a lower surface of each of the through vias in the first group, and
in a cross section parallel to a front surface of the first substrate, a cross-sectional area of the upper surface of the extended through via is larger than a cross-sectional area of each of the through vias in the first group.

13. The semiconductor device according to claim 1, further comprising:
an array chip provided above the second chip, electrically connected to the first transistor and the second transistor, and including a memory cell array including a plurality of memory cells arranged in a stacking direction of the first substrate and the second substrate.

14. The semiconductor device according to claim 13, wherein
the second chip includes a plurality of pads bonded to the array chip,
in a cross section parallel to a front surface of the first substrate, a cross-sectional area of each of the plurality of pads is larger than a cross-sectional area of each of the through vias in the first group, and
the plurality of pads is disposed at a third pitch greater than the first pitch.

15. The semiconductor device according to claim 13, further comprising:
a first sense amplifier having the first transistor and the second transistor, wherein
the memory cell array includes a first bit line electrically connected to a first memory cell of the plurality of memory cells,
the second transistor is electrically connected to the first transistor through one of the through vias in the first group, and
the first transistor is electrically connected to the first bit line through another one of the through vias in the first group.

16. The semiconductor device according to claim 13, further comprising:
a first row decoder having a third transistor, wherein
the first row decoder is in the first chip,
the memory cell array includes a first word line electrically connected to a first memory cell of the plurality of memory cells,
the third transistor is electrically connected to the first word line through one of the through vias in the second group.

17. The semiconductor device according to claim 16, wherein the second pitch is greater than the first pitch.

18. A method for manufacturing a semiconductor device, comprising:
forming a first chip having a first transistor and a first insulating layer located above the first transistor;
forming a second chip having a substrate and a first insulating film provided on the substrate;
bonding the first insulating film of the second chip onto the first insulating layer of the first chip;
forming a first insulating film region and a second insulating film region each penetrating the substrate; and
forming a first group of through vias penetrating the first insulating film, and a second group of through vias penetrating the second insulating film, the first group of through vias being arranged at a first pitch and the second group of through vias being arranged at a second pitch different from the first pitch.

19. The method for manufacturing a semiconductor device according to claim 18, further comprising:
forming a second transistor on the substrate;
forming a first contact connected to the second transistor; and
after forming the first contact, the first group of through vias, and the second group of through vias, forming a first wiring on the first contact, a first plurality of wirings on the first group of through vias in a same layer level as the first wiring, and a second plurality of wirings on the second group of through vias in the same layer level as the first wiring.

20. The method for manufacturing a semiconductor device according to claim 18, further comprising:
forming a second transistor on the substrate;
forming a first contact connected to the second transistor; and
forming a first wiring on the first contact, wherein
said forming the first group of through vias and the second group of through vias comprises forming the first group of through vias and the second group of through vias to have a same height as an upper surface of the first wiring after forming the first wiring.
